(19) United States
(12) Patent Application Publication
(10) Pub. No.: US 2012/0268995 A1
(43) Pub. Date: Oct. 25, 2012

(54) NON-VOLATILE SEMICONDUCTOR MEMORY DEVICE AND ELECTRONIC APPARATUS

(75) Inventors: Akira SUGIMOTO, Kyoto (JP); Satoshi Mishima, Osaka (JP); Masahiro Toki, Shiga (JP); Kazuyuki Kouno, Osaka (JP); Hirohito Kikukawa, Osaka (JP); Toshio Mukunoki, Nara (JP)

(73) Assignee: Panasonic Corporation, Osaka (JP)

(21) Appl. No.: 13/534,677

(22) Filed: Jun. 27, 2012

Related U.S. Application Data
(63) Continuation of application No. PCT/JP2011/000860, filed on Feb. 16, 2011.

(30) Foreign Application Priority Data
Feb. 22, 2010 (JP) 2010-036369

(51) Int. Cl. G11C 16/04

(52) U.S. Cl. 365/185.11; 365/185.18

(57) ABSTRACT

A memory cell array including non-volatile memory cells is divided into a first block including a non-volatile memory cell for accumulating a degradation over time and a second block including a non-volatile memory cell for storing data. A word line select circuit and a bit line select circuit select a first word line and a first bit line connected to the second block to access the non-volatile memory cell for storing data of the second block, and selects a second word line or a second bit line connected to the first block to apply a stress voltage to the non-volatile memory cell for accumulating the degradation over time of the first block, thereby automatically detecting ambient temperature and storing accumulated stress.

### CROSS-REFERENCE TO RELATED APPLICATIONS

This is a continuation of PCT International Application PCT/JP2011/000860 filed on Feb. 16, 2011, which claims priority to Japanese Patent Application No. 2010-036369 filed on Feb. 22, 2010. The disclosures of these applications including the specifications, the drawings, and the claims are hereby incorporated by reference in their entirety.

### BACKGROUND

The present disclosure relates to techniques of ensuring safe and reliable operation (preventing unsafe operation and hazards) of electronic apparatuses by managing a temperature and a system operating time.

In recent years, manufacturers of electronic apparatuses have been strictly required by the IEC 60730 etc. to take steps to ensure safety of their products. An electronic apparatus includes a large number of system components. Even for semiconductor parts, the manufacturers themselves provide a self-diagnosis function etc. in the device to ensure the safety in order to avoid problems when the device operates within guaranteed specifications. However, particularly recently, diversification and globalization of electronic apparatuses have advanced rapidly, and electronic apparatuses may be used at temperatures outside the guaranteed ambient temperature range which are not expected by the manufacturers. In this case, it is likely that a wear-out failure or a random failure of a system component which are caused by accumulated stress due to excessive heat or operating voltage leads to a system failure of an electronic apparatus. Therefore, some electronic apparatus manufacturers have taken steps to prevent a failure of system components.

In a conventional system, a temperature detector such as a thermistor is provided, and a warning is issued when the system is used at other than the guaranteed ambient temperatures, thereby ensuring safety of the system or preventing a failure of the system (see Japanese Patent Publication No. 2001-144243).

It has also been proposed that a temperature is detected based on temperature characteristics during rewrite operation of a flash memory (see Japanese Patent Publication No. H10-275492).

In conventional systems of electronic apparatuses, a temperature detector such as a thermistor is provided to monitor the system in order to predict a wear-out failure or a random failure of system components which are caused by accumulated stress. Therefore, there is an increase in the number of parts, disadvantageously leading to an increase in cost, power, and system control complexity.

Moreover, conventional electronic apparatuses require power supply for their operation. Therefore, stress cannot be detected in the absence of power supply. However, a degradation over time due to excessive stress of the electronic apparatus proceeds not only in the presence of power supply but also in the absence of power supply (i.e., even when the electronic apparatus is inactive in the absence of power supply, the electronic apparatus degrades over time due to an influence of ambient temperature). Therefore, the lack of information about stress during the absence of power supply leads to a significant decrease in the accuracy of prediction of the life of the electronic apparatus which is affected by excessive stress.

When a temperature is detected based on the temperature characteristics during rewrite operation of a flash memory, only a temperature as it is when there is a request from the system is detected, and therefore, accumulated environmental stress determined by a combination of a temperature and an operating time cannot be detected. Moreover, rewrite operation causes a degradation of a flash memory cell, disadvantageously leading to a decrease in the accuracy of temperature detection.

### SUMMARY

The present disclosure describes implementations of a technique of ensuring safety of an electronic apparatus by managing a temperature and a system operating time using a characteristic of a non-volatile memory cell.

A non-volatile semiconductor memory device according to the present disclosure utilizes a characteristic of a non-volatile memory cell sensitive to temperature or a voltage applied during an operating time. The non-volatile semiconductor memory device includes a non-volatile memory cell which accumulates excessive stress applied to an electronic apparatus, and a control circuit which reads a degree of the accumulated excessive stress from the non-volatile memory cell to find a degree of a degradation over time of the electronic apparatus, and controls operation of the electronic apparatus when necessary. The excessive stress is accumulated in a space in the non-volatile memory which is provided apart from a space for storing data. Voltage stress is applied to the space for accumulating the excessive stress during operation. As a result, detection of ambient temperature and automatic recording of stress accumulated due to a combination of temperature and the operating time can be simultaneously performed. In an example application, a circuit or means which adjusts a state of a threshold voltage etc. of a non-volatile memory may be employed in order to allow the non-volatile memory cell to detect stress more accurately.

As described above, according to the present disclosure, detection of ambient temperature and automatic recording of stress accumulated due to a combination of temperature and the operating time are implemented in a single chip, whereby a complicated control can removed from an electronic apparatus, and the number of parts can be decreased to reduce cost, resources, and power. Moreover, semiconductor components included in the non-volatile memory are already commonly and widely used in most electronic apparatuses, and therefore, the non-volatile memory can be implemented by directly using a process, a memory cell device, a read circuit, a control circuit, etc. for electronic apparatuses.

If the non-volatile semiconductor memory device of the present disclosure is incorporated into an electronic apparatus, the runaway of a system can be prevented, the state of safety of a system can be stored, the state of safety of a system can be notified, a system can be reset, etc., outside a guaranteed temperature environment. In addition, in example applications, a feedback function for improving the data retention property of an embedded non-volatile memory for storing data can be provided, power can be lowered by a frequency control at various temperatures, etc.

### BRIEF DESCRIPTION OF THE DRAWINGS

FIG. 1 is a block diagram showing an example configuration of a non-volatile semiconductor memory device according to an embodiment of the present disclosure.

FIG. 2 is a block diagram showing a variation of FIG. 1.

FIG. 3 is a diagram showing lines indicating theoretical degradations over time of a memory cell Vt of a flash memory at different temperatures, and a line indicating an actual degradation over time of the memory cell Vt.

FIG. 4 is a diagram showing lines indicating theoretical degradations over time at different memory cell Vts of a flash memory under different voltage conditions, and a line indicating an actual degradation over time of the memory cell Vt.

FIG. 5 is a timing diagram showing transition of word line voltages which occurs when a degradation over time is accumulated in the non-volatile semiconductor memory device of FIGS. 1 and 2.

FIG. 6 is another timing diagram showing transition of word line voltages which occurs when the degradation over time is accumulated in the non-volatile semiconductor memory device of FIGS. 1 and 2.

FIG. 7 is still another timing diagram showing transition of word line voltages which occurs when the degradation over time is accumulated in the non-volatile semiconductor memory device of FIGS. 1 and 2.

FIG. 8 is still another timing diagram showing transition of word line voltages which occurs when the degradation over time is accumulated in the non-volatile semiconductor memory device of FIGS. 1 and 2.

FIG. 9 is a flow chart of operation of reading out a degree of the degradation over time in response to an external request signal in the non-volatile semiconductor memory device of FIGS. 1 and 2.

FIG. 10 is a flow chart of operation of reading the degree of the degradation over time in response to an own regular request signal in the non-volatile semiconductor memory device of FIGS. 1 and 2.

FIG. 11 is a diagram showing an example configuration of a semiconductor system including the non-volatile semiconductor memory device of the present disclosure.

FIG. 12A is a diagram a distribution of the memory cell Vt of a flash memory in an initial state.

FIG. 12B is a diagram a state of the distribution of the memory cell Vt of a flash memory after the degradation over time.

FIG. 13 is a diagram showing lines indicating theoretical degradations over time of the memory cell Vt of a flash memory where rewrite operation is performed different numbers of times.

FIG. 14 is a block diagram showing another example configuration of the semiconductor system including the non-volatile semiconductor memory device of the present disclosure.

FIG. 15 is a flow chart showing operation of the semiconductor system of FIG. 14.

FIG. 16 is a block diagram showing an example configuration of an electronic apparatus including the non-volatile semiconductor memory device of the present disclosure.

FIG. 17 is a block diagram of a microcomputer with an embedded flash memory.

FIG. 18 is a diagram showing a detailed configuration of a sensor cell array of FIG. 17.

FIG. 19A is a diagram showing an operating state of a sensor cell of FIG. 18 in the presence of applied thermal stress.

FIG. 19B is a diagram showing an operating state of the sensor cell of FIG. 18 during reading of the state.

FIG. 20A is a diagram showing an operating state of another sensor cell of FIG. 18 in the presence of applied voltage stress.

FIG. 20B is a diagram showing an operating state of the sensor cell of FIG. 18 during reading of the state.

FIG. 21 is a diagram showing shows typical failure rate curves of an electronic apparatus or electronic part and a semiconductor device.

FIG. 22 is a diagram showing a graph and equation for estimating a life based on the Arrhenius model.

FIG. 23 is a diagram showing a graph and equation for estimating a life based on the Eyring model.

FIG. 24 is a diagram showing theoretical lines indicating the degradation over time of the memory cell Vt of a flash memory under different temperature conditions.

FIG. 25 is a diagram showing a relationship between the change amount of the memory cell Vt and a temperature in a predetermined time Ts of FIG. 24.

FIG. 26 is diagram showing a life determination table in which thermal stress and voltage stress are combined.

FIG. 27 is a block diagram showing an example semiconductor system including the non-volatile semiconductor memory device of the present disclosure, where the semiconductor system includes a plurality of chips.

### DETAILED DESCRIPTION

Embodiments of the present disclosure will be described in detail hereinafter with reference to the accompanying drawings.

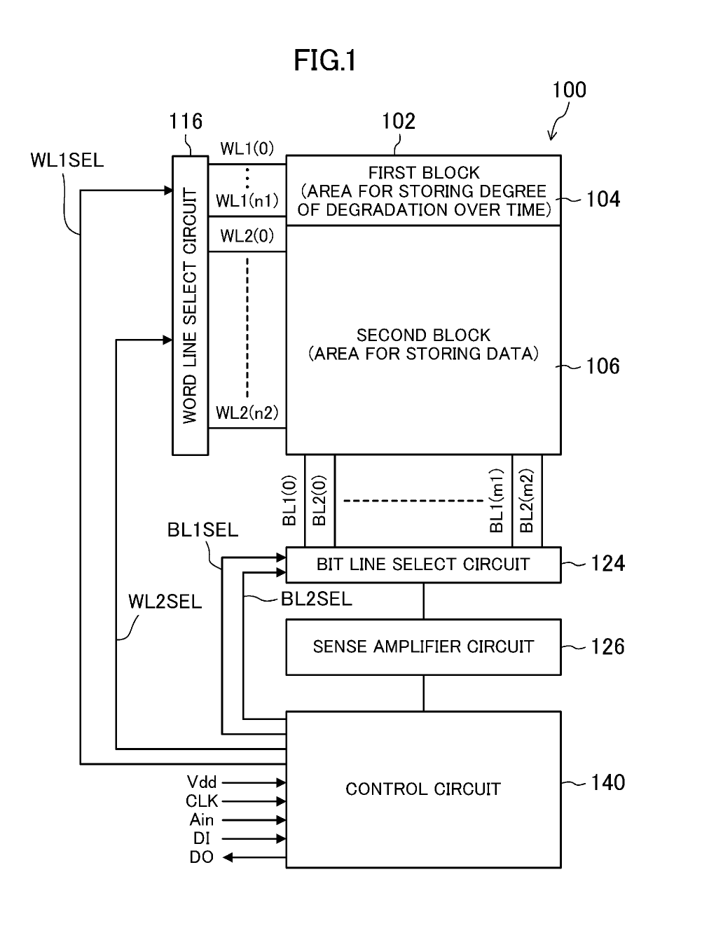

FIG. 1 shows an example configuration of a non-volatile semiconductor memory device according to an embodiment of the present disclosure. The non-volatile semiconductor memory device 100 of FIG. 1 includes a memory cell array 102 including a plurality of blocks which can be erased separately, i.e., a first block (an area for storing a degree of a degradation over time) 104 and a second block (an area for storing data) 106. The memory cell array 102 includes non-volatile memory cells arranged in a grid pattern, i.e., provided at intersections of word lines WL1(0)-WL1(n1) and bit lines BL1(0)-BL1(m1) or intersections of word lines WL2(0)-WL2(n2) and bit lines BL2(0)-BL2(m2).

A word line select circuit 116 receives a word line select signal WL1SEL and a word line select signal WL2SEL. The word line select signal WL1SEL is used to supply a required potential to the word lines WL1(0)-WL1(n1) of the first block 104. The word line select signal WL2SEL is used to supply a required potential to the word lines WL2(0)-WL2(n2) of the second block 106.

The bit lines BL1(0)-BL1(m1) of the first block 104 and the bit lines BL2(0)-BL2(m2) of the second block 106 are connected to a bit line select circuit 124. A required bit line selected based on a bit line select signal BL1SEL for selecting the first block 104 and a bit line select signal BL2SEL for selecting the second block 106, which are input to the bit line select circuit 124. The selected bit line is connected to a sense amplifier circuit 126, and data is input and output via a control circuit 140. The control circuit 140 externally receives a power supply Vdd, a clock signal CLK, and an input address Ain, and are connected to external circuitry via an input signal line DI and an output signal line DO.

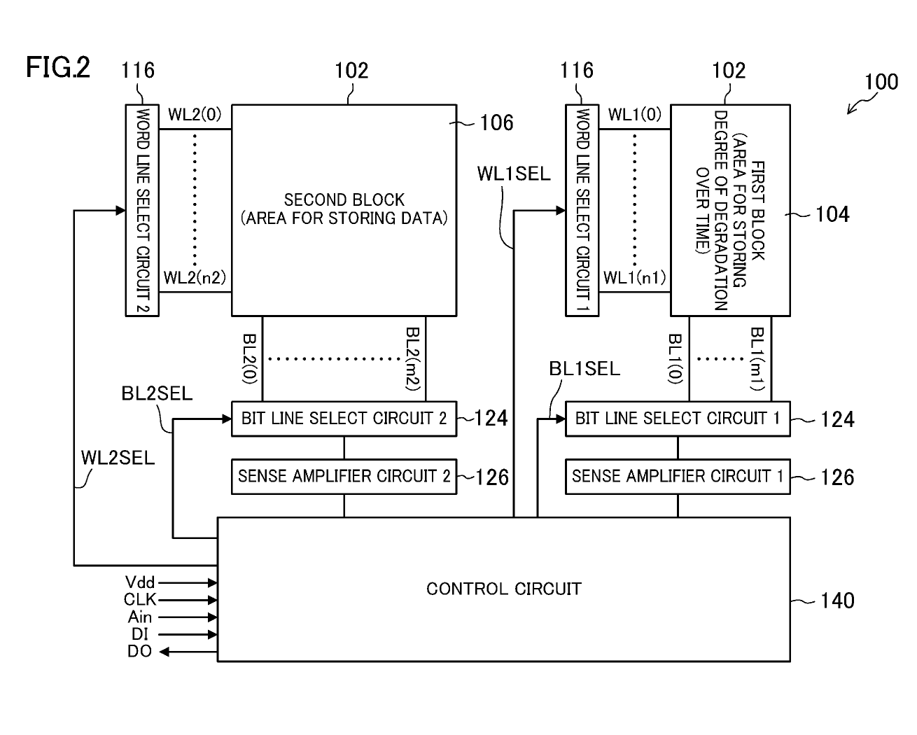

FIG. 2 shows a variation of FIG. 1. In FIG. 1, the word line select circuit 116, the bit line select circuit 124, and the sense amplifier circuit 126 are shared by the first and second blocks 104 and 106. Alternatively, of course, as shown in FIG. 2, the word line select circuit 116, the bit line select circuit 124, and the sense amplifier circuit 126 may be provided for the first and second blocks 104 and 106 separately, and even in this case, similar advantages can be obtained.

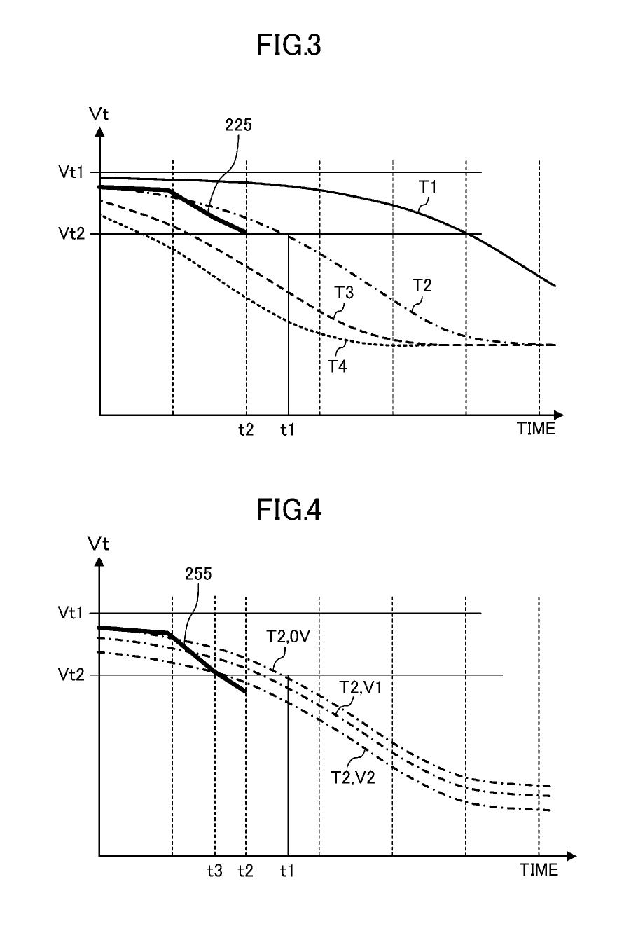

Incidentally, in the present disclosure, a characteristic of a change in the threshold voltage (Vt) of a memory cell due to stress shown in FIGS. 3 and 4 is utilized. A flash memory will be described hereinafter. The non-volatile semiconductor memory device of the present disclosure is not limited to flash memories.

FIG. 3 is a diagram showing lines indicating theoretical degradations over time of the memory cell Vt of the flash memory at different temperatures T1, T2, T3, and T4, and a line 225 indicating an actual degradation over time of the memory cell Vt. The vertical axis indicates memory cell Vts and the horizontal axis indicates time. Vt1 and Vt2 indicate memory cell Vts and t1 and t2 indicate time.

As can be seen from FIG. 3, for example, if a cumulative use time t1 is guaranteed at the temperature T2 in the semiconductor memory device of the present disclosure, then when the memory cell Vt is lower than or equal to Vt2 (the intersection of the time t1 and the theoretical line of the temperature T2), it can be determined that a guaranteed time corresponding to the temperature T2 has expired. For example, if a change occurs as indicated by a curve 225, it can be determined that there is a limit of the guaranteed range at the time t2 when the memory cell Vt is equal to the determination level Vt2.

FIG. 4 is a diagram showing lines indicating theoretical degradations over time at different memory cell Vts, i.e., voltages 0V, V1, and V2 (temperature: T2) of the flash memory, and a line 255 indicating an actual degradation over time of the memory cell Vt. Vt1 and Vt2 indicate memory cell Vts, and t1, t2, and t3 indicate time.

For example, when a voltage is applied to a memory cell during read operation of the flash memory, a change in the memory cell Vt (called “read disturb”) occurs along with a change in temperature. Therefore, compared to when the memory cell Vt changes in the absence of an applied voltage as indicated by the curve 225 of FIG. 3, the presence of an applied voltage causes the memory cell Vt to change earlier or more sharply as indicated by the curve 255 of FIG. 4, and also causes the time at which the determination level Vt2 is reached to be t3 which is earlier than that of the curve 225. Therefore, by observing a change in the memory cell Vt in the presence of an applied voltage as well as in the absence of an applied voltage, a change in the memory cell Vt containing a degradation over time due to read operation as well as a degradation over time due to temperature can be checked.

Next, operation of the non-volatile semiconductor memory device 100 of FIGS. 1 and 2 will be described.

Firstly, operation of accumulating a degradation over time will be described. The control circuit 140 outputs, based on the clock signal CLK and the input address Ain input thereto, the word line select signal WL1 SEL to the first block 104, the word line select signal WL2SEL to the second block 106, the bit line select signal BL1SEL to the first block 104, and the bit line select signal BL2SEL to the second block 106, respectively. A word line and a bit line of each block are selected based on the word line select signal and the bit line select signal, and a voltage is supplied to the selected word line and bit line.

FIG. 5 is a timing diagram showing transition of word line voltages which occurs when a degradation over time is accumulated in the non-volatile semiconductor memory device 100 of FIGS. 1 and 2. Here, shown are input waveforms of the clock signal CLK, the input address Ain, a selected word line WL1(x) of the first block 104, and a selected word line WL2(y) of the second block 106. When the second block 106 is accessed, the word line WL2(y) of the second block 106 is selected and supplied with a voltage based on the clock signal CLK and the input address Ain. At the same time when the voltage is applied to the word line of the second block 106, a voltage is supplied to the word line WL1(x) of the first block 104. When the accessing to the second block 106 is completed and the applying of the voltage to the word line WL2(y) is ended, the applying of the voltage to the word line WL1(x) of the first block 104 is also ended. As described above, the accumulation of the degradation over time is performed by applying a voltage to the word line WL1(x) of memory cells of the first block 104.

Note that, in FIG. 5, in the method of accumulating the degradation over time, when a word line WL2(y) of the second block 106 is selected, a word line WL1(x) of the first block 104 is selected and supplied with a voltage. Alternatively, bit lines may be used instead of word lines, i.e., at the same time when a bit line BL2(y) of the second block 106 is selected, a voltage may be applied to a selected bit line BL1(x) of the first block 104. In this case, similar advantages can be obtained.

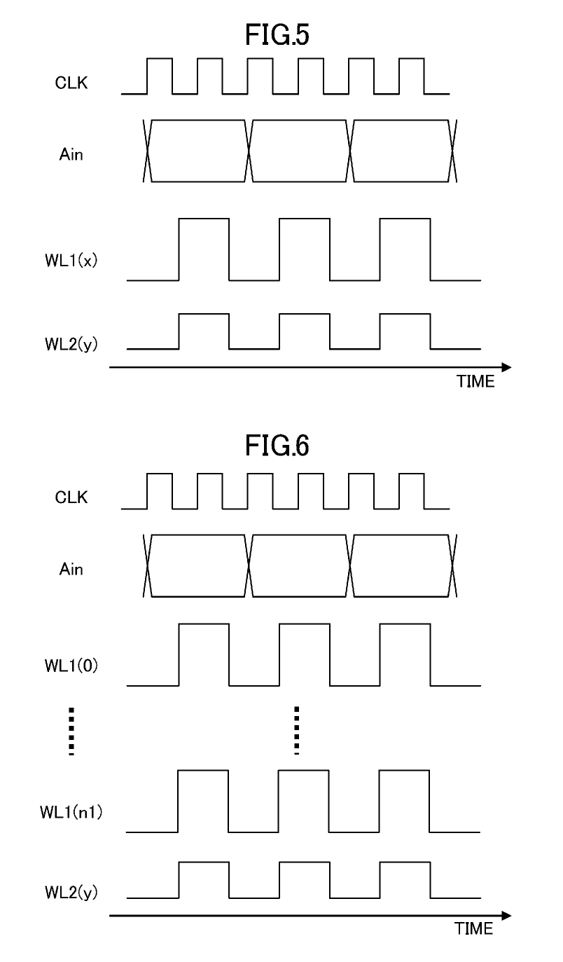

FIG. 6 is another timing diagram showing transition of word line voltages which occurs when the degradation over time is accumulated in the non-volatile semiconductor memory device 100 of FIGS. 1 and 2. Here, shown are input waveforms of the clock signal CLK, the input address Ain, the word lines WL1(0)-WL1(n1) of the first block 104, and a selected word line WL2(y) of the second block 106. When the second block 106 is accessed, the word line WL2(y) of the second block 106 is selected and supplied with a voltage based on the clock signal CLK and the input address Ain. At the same time when the voltage is applied to the word line WL2(y) of the second block 106, a voltage is applied to all the word lines WL1(0)-WL1(n1) of the first block 104. When the accessing to the second block 106 is completed and the applying of the voltage to the word line WL2(y) is ended, the applying of the voltage to the word lines WL1(0)-WL1(n1) of the first block 104 is ended. As described above, by applying a voltage to the word lines WL1(0)-WL1(n1) of the memory cells of the first block 104, a voltage can be simultaneously applied even when memory cells provided on different word lines of the second block 106 have different degrees of the degradation over time, whereby a plurality of degradations over time can be accumulated.

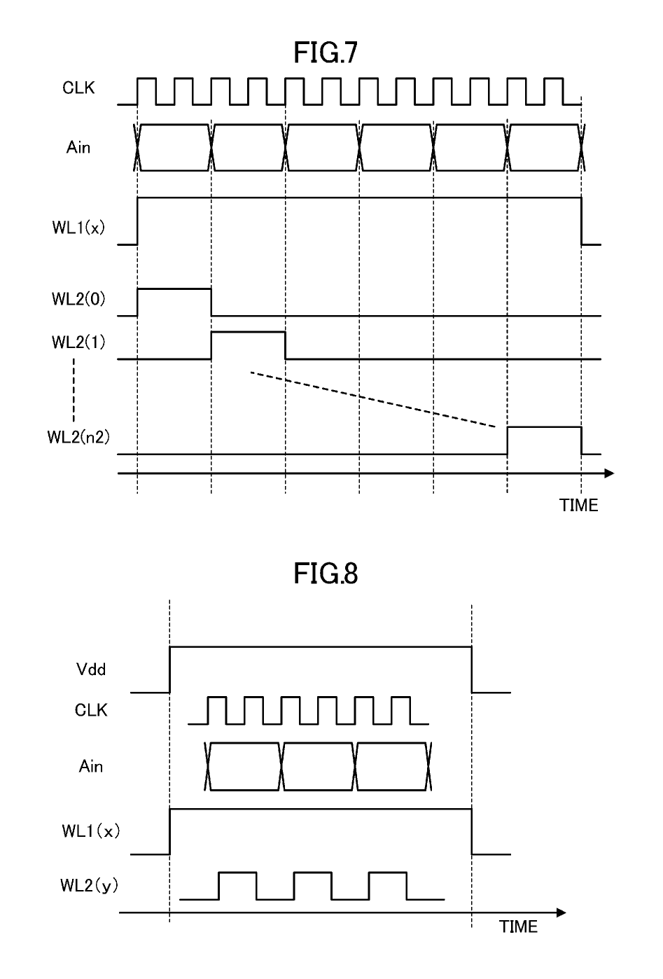

FIG. 7 is still another timing diagram showing transition of word line voltages which occurs when the degradation over time is accumulated in the non-volatile semiconductor memory device 100 of FIGS. 1 and 2. Here, shown are input waveforms of the clock signal CLK, the input address Ain, a selected word line WL1(x) of the first block 104, and the word lines WL2(0)-WL2(n2) of the second block 106. When the second block 106 is accessed, the word lines WL2(0)-WL2(n2) of the second block 106 are successively selected and supplied with a voltage based on the clock signal CLK and the input address Ain. At the same time when the voltage is supplied to any of the word lines of the second block 106, a voltage is applied to the word line WL1(x) of the first block 104. When the accessing to the second block 106 is completed and the applying of the voltage to all the selected word lines WL2(0)-WL2(n2) is ended, the applying of the voltage to the word line WL1(x) of the first block 104 is also ended. As described above, when the word lines WL2(0)-WL2(n2) of the memory cells of the second block 106 are selected, a voltage is invariably applied to the word line WL1(x) of memory cells of the first block 104, whereby the degradation over time affected by a time during which any of the word lines of memory cells of the second block 106 is selected can be accumulated.

FIG. 8 is still another timing diagram showing transition of word line voltages which occurs when the degradation over time is accumulated in the non-volatile semiconductor memory device 100 of FIGS. 1 and 2. Here, shown are input waveforms of the power supply Vdd of the non-volatile semiconductor memory device 100, the clock signal CLK, the input address Ain, a selected word line WL1(x) of the first block 104, and a selected word line WL2(y) of the second block 106. When the second block 106 is accessed, the power supply Vdd of the non-volatile semiconductor memory device 100 is supplied, and at the same time, a voltage is applied to the word line WL1(x) of the first block 104.

Thereafter, the word line WL2(y) of the second block 106 is selected and supplied with a voltage based on the clock signal CLK and the input address Ain. When the accessing is completed, the applying of the voltage to the selected word line WL2(y) is ended. The power supply Vdd of the non-volatile semiconductor memory device 100 is ended, and at the same time, the applying of the voltage to the word line WL1(x) of the first block 104 is also ended. As described above, when the power supply Vdd of the non-volatile semiconductor memory device 100 is applied, a voltage is invariably applied to the word line WL1(x) of memory cells of the first block 104, whereby the degradation over time affected by a time during which power is supplied can be accumulated.

Next, operation which is performed when the degradation over time is read out will be described.

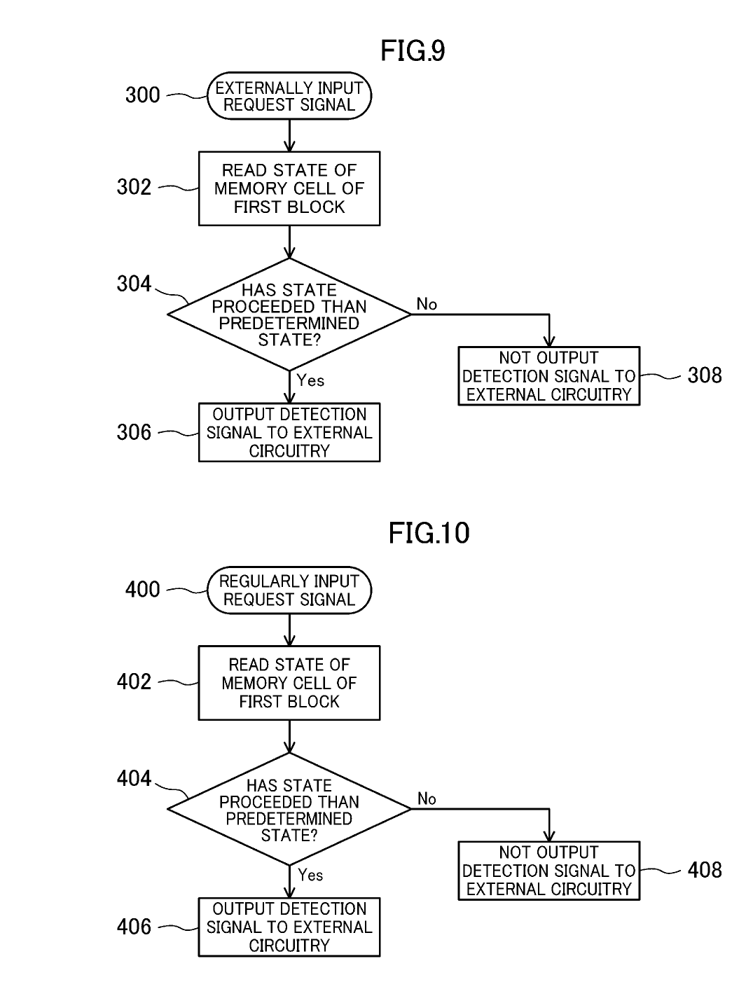

FIG. 9 is a flow chart of operation of reading out the degree of the degradation over time in response to a request signal from circuitry external to the non-volatile semiconductor memory device 100 of FIGS. 1 and 2. When the request signal is externally input to the control circuit 140 of the non-volatile semiconductor memory device 100 (300), the control circuit 140 outputs the word line select signal WL1SEL and the bit line select signal BL1SEL to the first block 104, so that a memory cell of the first block 104 is selected, and a state of the memory cell is read out (302). The sense amplifier circuit 126 detects or determines whether or not the read memory cell state has proceeded further than a predetermined memory cell state (304). If the determination result is positive, a detection signal indicating that the degradation over time has proceeded is output via the control circuit 140 (306). When the determination result is negative, the detection signal is not output (308). As a result, the degree of the degradation over time can be detected based on whether or not the detection signal indicating that the degradation over time has proceeded due to the operating temperature and operating time has been output.

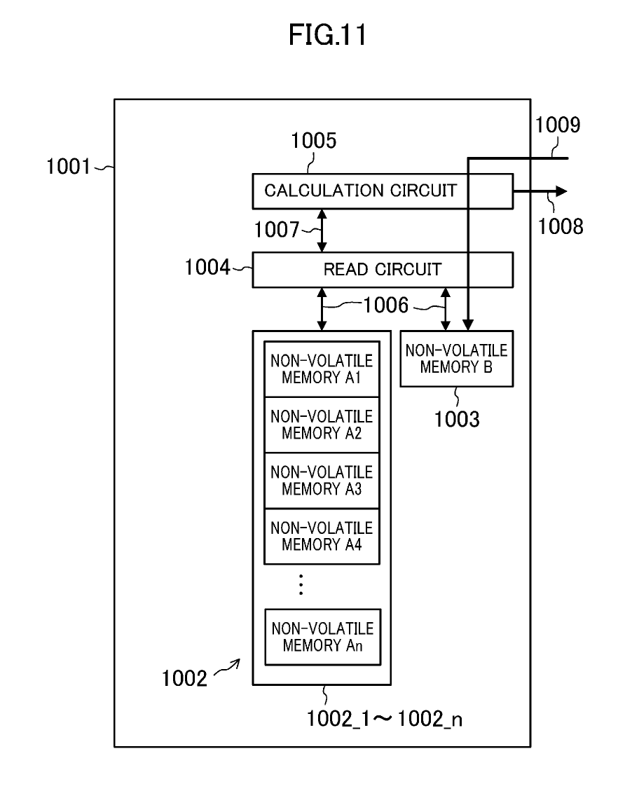

FIG. 10 is a flow chart of operation of reading the degree of the degradation over time in response to an own regular request signal of the non-volatile semiconductor memory device 100 of FIGS. 1 and 2. When a request signal is regularly input from the non-volatile semiconductor memory device 100 to the control circuit 140 (400), the control circuit 140 outputs the word line select signal WL1SEL and the bit line select signal BL1SEL to the first block 104, so that a memory cell of the first block 104 is selected and the state of the memory cell is read out (402). The sense amplifier circuit 126 determines whether or not the read memory cell state has proceeded further than a predetermined memory cell state (404). If the determination result is positive, a detection signal indicating that the degradation over time has proceeded is output via the control circuit 140 (406). When the determination result is negative, the detection signal is not output (408). As a result, the degree of the degradation over time can be detected based on whether or not the detection signal indicating that the degradation over time has proceeded due to the operating temperature and operating time has been output.

FIG. 11 shows an example configuration of a semiconductor system including the non-volatile semiconductor memory device of the present disclosure. In FIG. 11, the semiconductor system 1001 includes n non-volatile memories A 1002_1-1002_n (n is an integer) (collectively represented by a reference character 1002), a non-volatile memory B 1003, a read circuit 1004 for the non-volatile memories (A and B) 1002 and 1003, a calculation circuit 1005, a read signal line 1006, a signal line 1007, an output terminal 1008 from the calculation circuit 1005, and a signal input line 1009 to the non-volatile memory (B) 1003. The read circuit 1004 includes, for example, a word line select circuit, a bit line select circuit, a sense amplifier circuit, etc.

The semiconductor system 1001 includes, for example, a single semiconductor chip, a portion of a semiconductor chip, or a plurality of semiconductor chips. Examples of the non-volatile memory (A, B) 1002, 1003 include, in addition to a flash memory, a magneto-resistive random access memory (MRAM), a resistive random access memory (ReRAM), etc. A flash memory will be described hereinafter as the non-volatile memory (A, B) 1002, 1003, but the present disclosure is not intended to be limited to a flash memory.

In the non-volatile memory (A, B) 1002, 1003 which is, for example, a flash memory, the memory cell Vt is set to a predetermined level (e.g., the higher Vt1) during, for example, the manufacturing process.

The signal input line 1009 is input to the non-volatile memory (B) 1003. The signal input line 1009 is used to apply a voltage to, or access, a memory cell in the non-volatile memory (B) 1003, for example, when a non-volatile memory other than the non-volatile memory (B) 1003 provided in the semiconductor system 1001 is accessed, when the semiconductor system 1001 is driven, or when a system including the semiconductor system 1001 is driven. Here, the term “access” means operation of reading a non-volatile memory, for example.

The flash memory which is the non-volatile memory (A, B) 1002, 1003 has a memory cell Vt which changes depending on a temperature at which a voltage is applied and a time during which the voltage is applied (see FIG. 3). In actual use, it is not often that the flash memory continues to be used at a constant temperature. For example, the memory cell Vt changes as indicated by the curve 225.

For example, if the system of the present disclosure guarantees the cumulative use time t1 at the temperature T2, then when an intersection (the memory cell Vt) of the time t1 and the theoretical line of the temperature T2 is Vt2 or less in FIG. 3, it can be determined that the guaranteed time corresponding to the temperature T2 has expired. Therefore, the read circuit 1004 reads the memory cell Vt of the non-volatile memory (A) 1002 from the signal line 1006 and performs calculation at appropriate intervals, whereby it can be determined whether or not a cumulative temperature time during which the system has been used is within the guaranteed range, for example. Specifically, if the memory cell Vt changes as indicated by the curve 225 of FIG. 3, it can be determined that there is a limit of the guaranteed range at the time t2 when the memory cell Vt is equal to the determination level Vt2.

In the flash memory which is the non-volatile memory (B) 1003, when the semiconductor system 1001 is driven or when a system including the semiconductor system 1001 is driven, access from the signal line 1009 (e.g., reading of the flash memory) causes a change (called “read disturb”) in the memory cell Vt in combination with a change in temperature. A change amount of the memory cell Vt is derived from a bias applied to the memory cell during read operation and a time during which the bias is applied, and therefore, the time can be calculated from the change amount and the applied bias.

The read circuit 1004 reads the memory cell Vt of the non-volatile memory (B) 1003 from the signal line 1006 at appropriate intervals. The calculation circuit 1005 calculates a difference between the memory cell Vt of the non-volatile memory (B) and the memory cell Vt of the non-volatile memory (A) 1002, which are read out via the signal line 1007, to obtain a system drive time.

Note that an example has been described in which the memory cell Vt is read by accessing the non-volatile memory (B) 1003 via the signal input line 1009, and a change in the memory cell Vt is read disturb. Any other techniques of obtaining the change in the memory cell Vt separately from temperature may be used.

The calculation circuit 1005 outputs, from the output terminal 1008, a signal under predetermined determination conditions with respect to a temperature, a time, and a system drive time which the semiconductor system 1001 or the system including the semiconductor system 1001 has been affected.

The output terminal 1008 may be connected to the semiconductor system 1001 itself or the system including the semiconductor system 100, depending on the settings of the determination conditions. In this case, for example, the output terminal 1008 may be used to issue a warning about the use at out-of-specification temperature or for more than the guaranteed time, to control operation, or to stop the system itself. As a result, it is possible to prevent a wear-out failure of a product, for example.

The non-volatile memory (A, B) 1002, 1003 can hold the memory cell Vt even in the absence of power supply and can change the memory cell Vt even in the absence of power supply due to ambient temperature. Conventionally, in order to provide a similar configuration, a memory circuit for storing history, a circuit for detecting a temperature, and a circuit for measuring a time are required. In the present disclosure, the memory circuit itself can both detect a temperature and measure a time, resulting in a reduction in the number of parts and the size.

Incidentally, the non-volatile memory (A, B) 1002, 1003 may be a single non-volatile memory cell. Even in this case, the advantages of the present disclosure can be obtained. However, in view of variations in characteristics etc., the determination level is limited. Therefore, the non-volatile memory (A, B) 1002, 1003 may include a plurality of memory cells, i.e., a memory cell array. In this case, by reading a distribution of the memory cell Vts, the accuracy of detection of a temperature and a system use time can be improved.

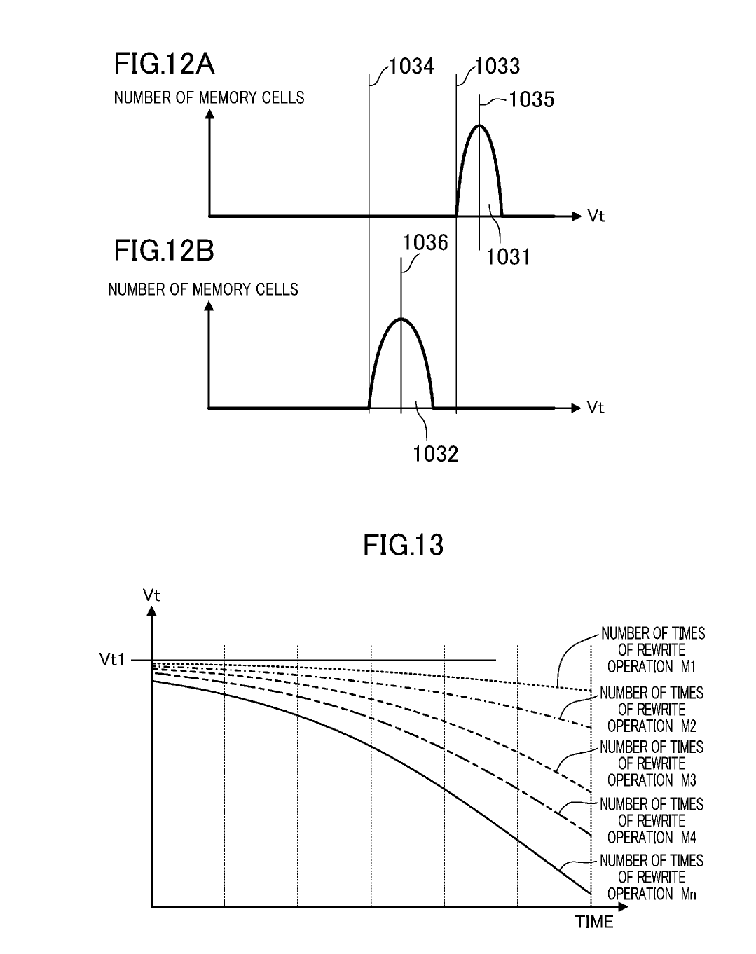

FIGS. 12A and 12B are diagrams showing a distribution of the memory cell Vt of a flash memory. FIG. 12A shows an initial state, and FIG. 12B shows a state after the degradation over time. The horizontal axis indicates the memory cell Vt, and the vertical axis indicates the number of memory cells. A problem with the accuracy and an improvement in the accuracy will be described hereinafter with reference to FIGS. 12A and 12B.

FIG. 12A shows a distribution of the memory cell Vt which is obtained after writing the memory cell Vt to a predetermined high level during the manufacturing process, for example. On the other hand, FIG. 12B shows a distribution of the memory cell Vt which is obtained after an actual use time. A reference character 1031 indicates a distribution of the memory cell Vt which is obtained when write operation is performed. A reference character 1032 indicates a distribution of the memory cell Vt which is obtained after an actual use time. A reference character 1033 indicates a verify level for write operation. A reference character 1034 indicates a determination level. A reference character 1035 indicates a value of Vt at which the number of memory cells is largest in the memory cell Vt distribution 1031. A reference character 1036 indicates a value of Vt at which the number of memory cells is largest in the memory cell Vt distribution 1032.

For the non-volatile memory (A, B) 1002, 1003 which is, for example, a flash memory, the memory cell Vt is set to a predetermined level (the write verify level 1033) or more during the manufacturing process, for example. In this case, the memory cell Vt has the distribution 1031 based on variations in the cells of the array. Assuming that the memory cell Vt distribution has transitioned from that state to, for example, the distribution 1032 after the actual use of the system of the present disclosure, the lowest memory cell Vt reaches the determination level 1034 due to the variations in the cells of the array.

For example, if each non-volatile memory (A, B) 1002, 1003 includes a single non-volatile memory cell, the memory cell may have the lowest memory cell Vt, and therefore, the determination is more quickly performed. Conversely, if the cell has a high Vt, the determination is more slowly performed. Therefore, there are variations in the determination time, depending on the memory cell used.

This problem is alleviated by configuring the non-volatile memory (A, B) 1002, 1003 using a plurality of memory cells, i.e., a memory cell array, and using a distribution of the memory cell Vt. Specifically, by using the values 1035 and 1036 of Vt at which the number of memory cells is largest in the memory cell Vt distribution, the determination can be performed with respect to the behavior of an average cell in the array with variations between each memory cell being reduced. The values 1035 and 1036 of Vt are not limited to that of the same cell at each time, and are each an average value of Vt of the array including a plurality of cells. As a result, the accuracy of the determination can be improved. This advantage can be easily achieved using a memory cell array, a cell number measurement circuit, etc.

The accuracy of the determination can be further improved using a plurality of blocks having different change amounts due to temperature etc. For example, when the non-volatile memory (A) 1002 includes n non-volatile memories 1002_1-1002_n, the n non-volatile memories 1002_1-1002_n are rewritten different numbers of times (e.g., the non-volatile memory 1002_1 is previously rewritten once, the non-volatile memory 1002_2 is previously rewritten ten times, and the non-volatile memory 1002_3 is previously rewritten 100 times). Assuming this, the aforementioned configuration is provided.

FIG. 13 is a diagram showing lines indicating theoretical degradations over time of the memory cell Vt where the n non-volatile memories 1002_1-1002_n are rewritten different numbers of times M1-Mn (at the same temperature). The vertical axis indicates the memory cell Vt and the horizontal axis indicates time.

It is known that, in most non-volatile memories, the activation energy varies depending on the number of times of rewrite operation, and the change over time varies depending on the number of times of rewrite operation under the same temperature condition. Therefore, for example, even if the memory cell Vts are set to the predetermined level Vt1 during the manufacturing process and the memory cells are used under the same conditions, the change amount varies among the memory cells. Therefore, by setting each configuration to an appropriate determination level and performing the determination based on results from the set levels, the accuracy of the determination can be improved.

Although different numbers of times of rewrite operation are performed for illustrative purposes, any other features that cause the activation energy indicating a change amount due to temperature to vary may be used, including a change in a memory cell size, a memory thickness difference, etc.

An optimum improvement in accuracy is selected based on all of a required accuracy, chip area, ease of the process, etc.

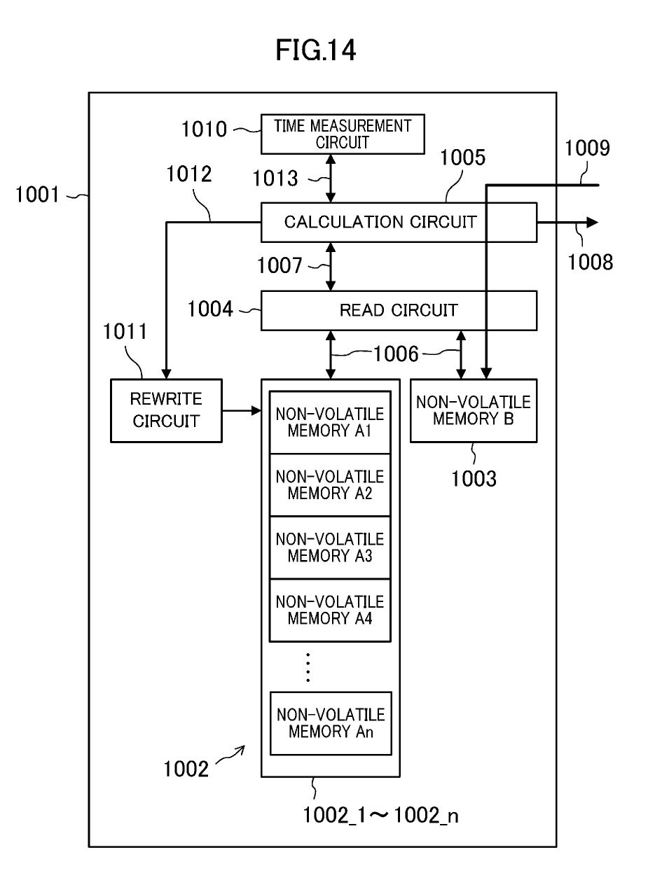

FIG. 14 shows another example configuration of the semiconductor system 1001 including the non-volatile semiconductor memory device of the present disclosure. In FIG. 14, the semiconductor system 1001 includes a time measurement circuit 1010, a rewrite circuit 1011, a signal line 1012 from the calculation circuit 1005 to the rewrite circuit 1011, and a signal line 1013 between the time measurement circuit 1010 and the calculation circuit 1005.

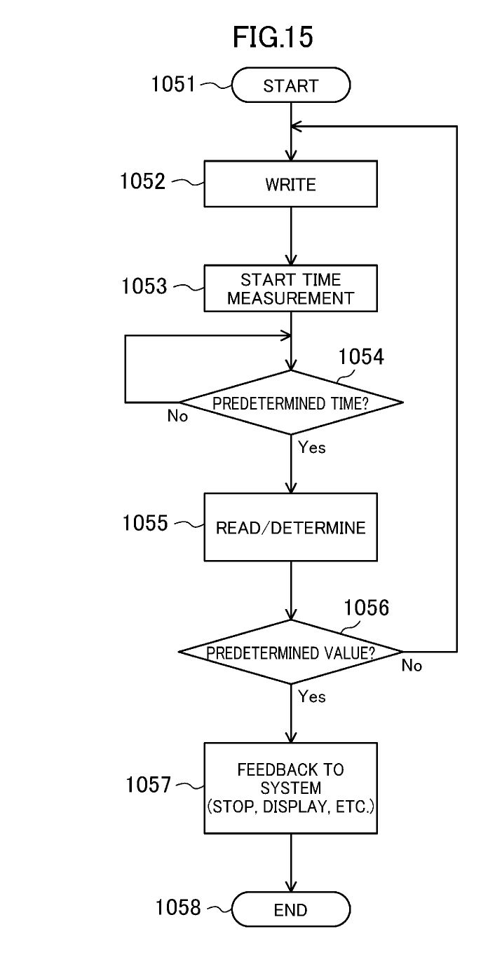

FIG. 15 is a flow chart showing operation of the semiconductor system 1001 of FIG. 14. In FIG. 15, a reference character 1051 indicates a start point, a reference character 1058 indicates an end point, reference characters 1052, 1053, 1055, and 1057 indicates processes, and reference characters 1054 and 1056 indicate determination.

The semiconductor system 1001 of FIG. 14 includes, for example, a single semiconductor chip, a portion of a semiconductor chip, or a plurality of semiconductor chips. The non-volatile memory (A, B) 1002, 1003 is, for example, a flash memory, and the memory cell Vt is set to a predetermined level (e.g., a high memory cell Vt). The signal input line 1009 is input to the non-volatile memory (B) 1003. The signal input line 1009 is used to access a memory cell in the non-volatile memory (B) 1003 for, for example, read operation of the non-volatile memory, when the semiconductor system 1001 is being driven or when a system including the semiconductor system 1001 is being driven.

The time measurement circuit 1010 starts measuring a time from when the memory cell Vt of the non-volatile memory (A) 1002 is set to a predetermined level, i.e., write operation is performed on the non-volatile memory (A) 1002. When determining, via the signal line 1013, that a predetermined time has elapsed, the calculation circuit 1005 issues a read command via the signal line 1007. In response to the read command, the read circuit 1004 reads the memory cell Vt of the non-volatile memory (A) 1002 from the signal line 1006, and performs calculation to determine whether or not the cumulative temperature time for which the system has been used is within the guaranteed range.

After performing the determination, the calculation circuit 1005 outputs a signal from the output terminal 1008 if the determination result is that the cumulative temperature time is outside the guaranteed range, for example.

If the determination result is other than that described above, the calculation circuit 1005 outputs a signal via the signal line 1012 to the rewrite circuit 1011, the rewrite circuit 1011 sets the memory cell Vt of the non-volatile memory (A) 1002 to a predetermined level, i.e., performs write operation, so that the state returns to the initial state.

This is represented by the following system operating flow. As shown in FIG. 15, control starts from the start point 1051 and proceeds to step 1052 in which the rewrite circuit 1011 performs write operation on the non-volatile memory (A) 1002. Next, control proceeds from step 1052 to step 1053 in which the time measurement circuit 1010 performs time measurement. Control proceeds from step 1053 to determination step 1054 in which it is determined whether or not a predetermined time has elapsed. If the determination result is positive, the read circuit 1004 reads the non-volatile memory (A) 1002, and control proceeds to step 1055 in which the calculation circuit 1005 performs determination, and otherwise, control returns to determination step 1054 in which it is determined whether or not the predetermined time has elapsed.

Thereafter, control proceeds to step 1056 in which it is determined whether or not the determination result of step 1055 has a predetermined value. If the determination result is positive, control proceeds to step 1057 in which a feedback (e.g., ending, displaying, etc.) is performed on the system, and then proceeds to end step 1058, and otherwise, control proceeds back to step 1052 in which the rewrite circuit 1011 performs write operation on the non-volatile memory (A) 1002.

If the time measured by the time measurement circuit 1010 is set to be short, a temperature applied during the short time, i.e., instantaneous application of a temperature can be determined. There are some systems in which instantaneous application of a temperature as well as cumulative temperature application time are important. The present disclosure can easily achieve prevention of a wear and tear and a failure of such a system, for example.

Note that the read circuit 1004 reads the memory cell Vt of the non-volatile memory (B) 1003 from the signal line 1006 at appropriate intervals, and the calculation circuit 1005 calculates a difference between the memory cell Vt of the non-volatile memory (B) 1003 and the memory cell Vt of the non-volatile memory (A) 1002, which are read out via the signal line 1007, to obtain a system drive time as in the embodiment of FIG. 11.

According to this embodiment, a mechanism for detecting instantaneous application of a temperature can be provided in, for example, a single semiconductor chip, leading to a reduction in the number of parts, etc.

When the semiconductor system 1001 described above includes a plurality of semiconductor chips, then if, for example, the non-volatile memories (A and B) 1002 and 1003 and the read circuit 1004, and other components (the calculation circuit 1005 etc.), are implemented on separate chips, the non-volatile memories (A and B) 1002 and 1003 are used as a sensor block to record an applied temperature and its time, and the other components are used as a block to perform control and determination. Specifically, the sensor block is initially set by the control and determination block, and thereafter, only the sensor block is placed in an environment in which an applied temperature and its time are to be obtained, and thereafter, the control and determination block determines a temperature applied to the sensor block and its time, etc. Note that the control and determination block is not necessarily required for each separate sensor block, and the semiconductor system 1001 can be configured even if a single control and determination block is provided for a plurality of sensor blocks. As a result, the advantages of the present disclosure can be obtained at lower cost.

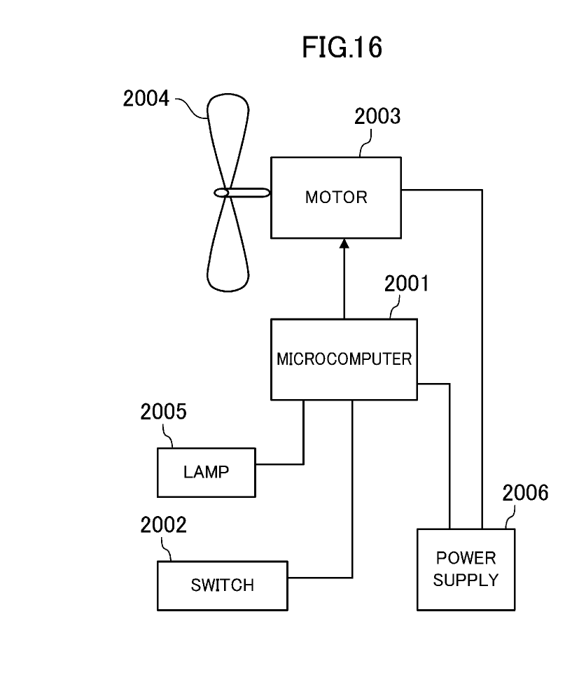

An embodiment which follows is an example in which a life prediction system of the present disclosure is added to a microcomputer including a flash memory for controlling a household appliance, whereby the life of the household appliance is managed. FIGS. 16-26 are diagrams for describing details of the embodiment.

Here, the reason why a household appliance and a microcomputer will be described is that household appliances and microcomputers are electronic apparatuses/parts which are commonly used in homes, and therefore, are appropriate as examples for describing the present disclosure for the purpose of putting the present disclosure into widespread use. The range within which the present disclosure is applicable is not intended to be limited to household appliances and microcomputers. The reason why a microcomputer with an embedded flash memory is used is that such a microcomputer is one that is most widely used, and a non-volatile memory cell required for the present disclosure is provided in the same chip, and therefore, the microcomputer is appropriate as a platform for achieving the life prediction system of the present disclosure. This is not intended to limit the type of the microcomputer used in the present disclosure.

In the description that follows, a specific type of household appliance which includes the present disclosure and a specific type of non-volatile memory cell which detects and accumulates stress may be described, but these are not intended to limit the types of household appliances and non-volatile memories. The specific household appliance and non-volatile memory are assumed only for ease of understanding.

Firstly, the figures showing details of this embodiment will be described.

FIG. 16 shows an example configuration of an electronic apparatus including the non-volatile semiconductor memory device of the present disclosure. Here, an electric fan will be described by way of example. A reference character 2001 is a microcomputer which controls operation of the electric fan. The microcomputer 2001 controls a motor 2003 in response to a signal from a switch block 2002 which receives a user's request so that the motor 2003 rotates a blade 2004 to generate wind. A reference character 2005 indicates a lamp block which indicates a state of the electric fan to the user. A reference character 2006 indicates a power supply block which externally receives household power supply (typically, 100 V) and converts the power supply into a voltage required for each block (the microcomputer 2001, the motor 2003, etc.) included in the electric fan.

Note that the microcomputer 2001 controls the motor 2003 in a complicated manner in order to operate the motor 2003 with high efficiency and satisfy various requests from the user. The switch block 2002 and the lamp block 2005 typically have a complicated configuration in order to receive various requests from the user and indicate a plurality of states of the electric fan to the user. Here, however, for ease of understanding, the control of the motor 2003 by the microcomputer 2001 and the function of the switch block 2002 are limited to an either-or choice, i.e., determination of whether or not to rotate the motor 2003. The function of the lamp block 2005 is also limited to turning on of the lamp when the life of the electric fan has expired. Note that an actual electric fan includes other components, which are not shown for the sake of simplicity.

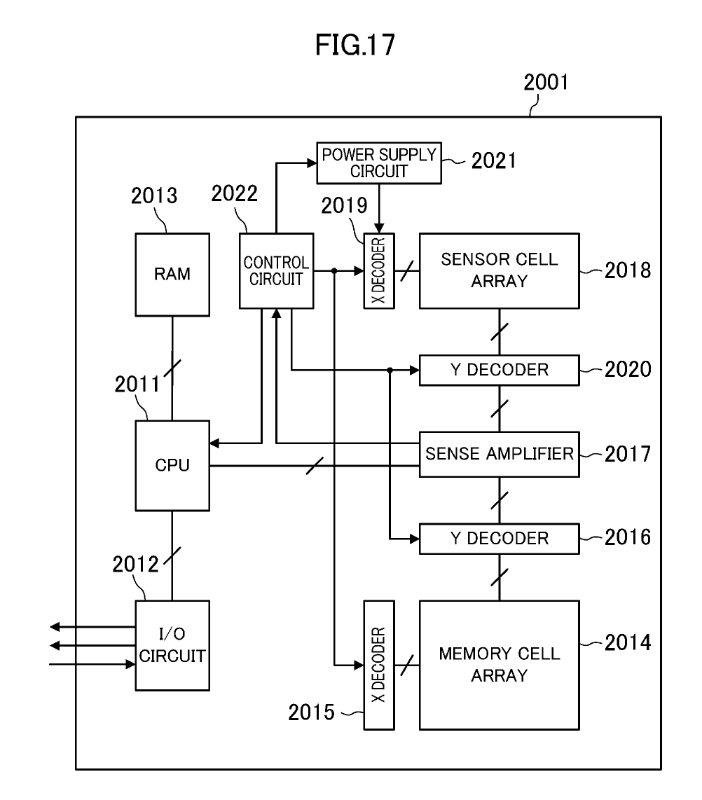

FIG. 17 is a block diagram of the microcomputer 2001 of FIG. 16. Here, a microcomputer with an embedded flash memory which is used as a read-only memory (ROM) for storing codes will be described by way of example. The microcomputer 2001 includes a central processing unit (CPU) 2011 which plays a central role in the operation of the microcomputer 2001, an input/output (I/O) circuit 2012 which includes a collection of ports which are used to exchange signals between the microcomputer 2001 and external circuitry, and a random access memory (RAM) 2013 which temporarily stores data. The microcomputer 2001 also includes a non-volatile memory which is a memory cell array 2014 including flash memory cells arranged in an array and stores codes which are to be executed by the CPU 2011, an X decoder 2015 and a Y decoder 2016 which select/drive a specific memory cell in the memory cell array 2014, and a sense amplifier 2017 which is a differential amplifier which determines data stored in the selected memory cell. The blocks 2014-2017 constitute the ROM. The aforementioned blocks are provided in a conventional microcomputer with an embedded flash memory. An actual microcomputer with an embedded flash memory includes, in addition to the blocks of FIG. 17, circuit blocks essential for the operation of the microcomputer, such as a power supply circuit, a reference potential circuit, a control circuit, etc., which are not related to the present disclosure and will not be described.

A reference character 2018 indicates a sensor cell array which detects and stores stress which degrades an electronic apparatus. Although a non-volatile memory cell is used as the sensor cell, an element (here, a flash memory cell included in the memory cell array 2014) used in the code storing ROM does not necessarily need to be used. This is because the memory cell array 2014 and the sensor cell array 2018 are provided for different purposes, and therefore, a type of non-volatile memory cell may be selected for each purpose. However, actually, it is difficult in technical terms to manufacture a product in which different types of non-volatile memory cells are provided on a single chip, and even if possible, the cost increases. Therefore, both the arrays 2014 and 2018 typically include the same type of non-volatile memory cells. In this embodiment, the sensor cell array 2018 includes flash memory cells. The number of cells included in the sensor cell array 2018 may be at least the minimum number of types of stress to be detected. If the number of types of stress is one, a plurality of sensor cells or an array structure is not necessarily required. However, the life is typically determined by a plurality of types of stress. With the knowledge of operation of an array structure, it is easy for those skilled in the art to implement the operation using a single cell. Therefore, this embodiment will be described using sensor cells having an array structure.

Reference characters 2019 and 2020 indicate an X decoder and a Y decoder for selecting/driving a specific sensor cell in the sensor cell array 2018. A power supply circuit 2021 supplies a portion of a bias voltage to be applied to the selected sensor cell. A control circuit 2022 is a circuit block which controls a series of operations related to the sensor cells.

The internal block configuration described above of the microcomputer 2001 is only for illustrative purposes, and the present disclosure is not limited to this. For example, although the single sensor cell array 2018 is provided, it is obvious to those skilled in the art to provide a plurality of sensor cell arrays 2018 when necessary. Although the sense amplifier 2017 is used for both the data determination of the memory cell array 2014 and the state determination of the sensor cell array 2018 and therefore is provided at a middle between the arrays 2014 and 2018 (i.e., an open array architecture), separate sense amplifiers may be provided for the respective arrays.

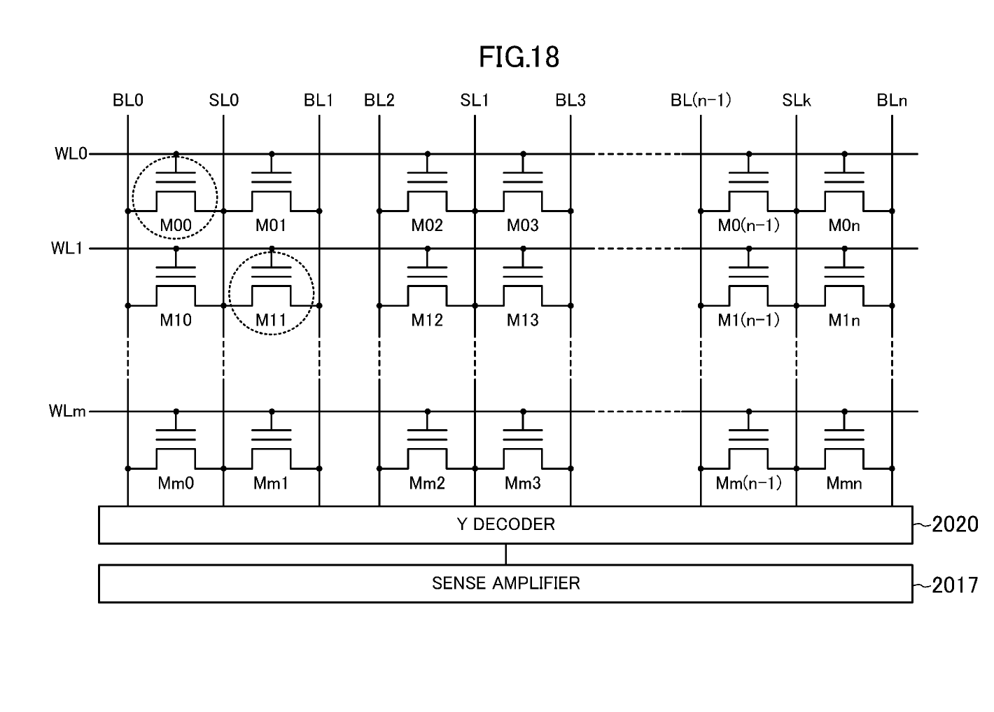

FIG. 18 is a diagram showing a detailed configuration of the sensor cell array 2018 of FIG. 17. Sensor cells M00-Mmn are arranged in an array. The gates of the cells are connected to word lines WL0-WLm, the sources are connected to source lines SL0-SLk, and the drains are connected to bit lines BL0-BLn. The word lines WL0-WLm are connected to the X decoder 2019, and the source lines SL0-SLk and the bit lines BL0-BLn are connected to the Y decoder 2020, and via these lines, a bias voltage can be applied to the sensor cells M00-Mmn and a signal can be input to and output from the sensor cells M00-Mmn. Note that the sensor cells M00-Mmn are here assumed to be floating gate flash memory cells, which perform write operation using channel hot electrons (CHE) and erase operation using Fowler-Nordheim (FN) current. Alternatively, various other types of flash memory cells may be used. In addition to the array structure of FIG. 18, various other array structures may be used, including a virtual ground array (VGA), a NAND array, etc.

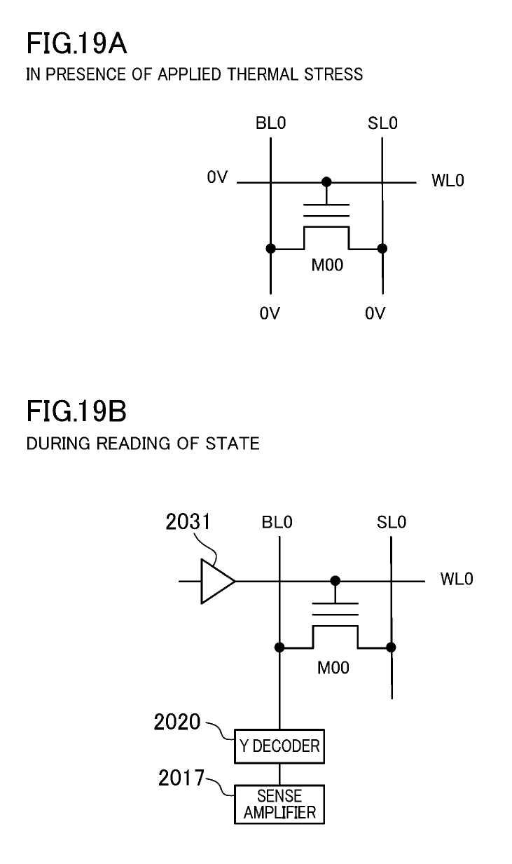

FIGS. 19A and 19B are diagrams showing operating states of the sensor cell MOO of FIG. 18. FIG. 19A shows the operating state in the presence of applied thermal stress. FIG. 19B shows the operating state during reading of the state. A reference character 2031 indicates a word line driver included in the X decoder 2019.

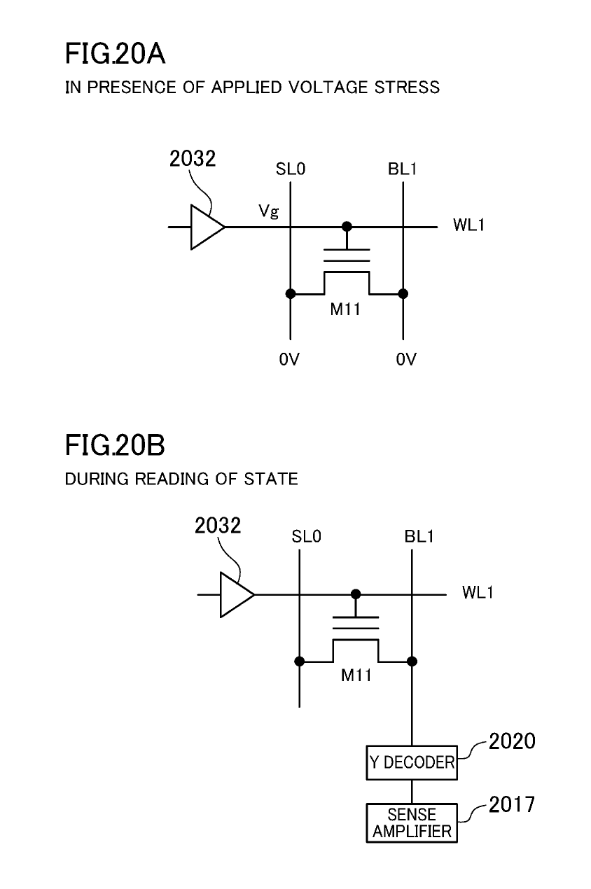

FIGS. 20A and 20B are diagrams showing operating states of another sensor cell M11 of FIG. 18. FIG. 20A shows the operating state in the presence of applied voltage stress. FIG. 20B shows the operating state during reading of the state. A reference character 2032 indicates a word line driver included in the X decoder 2019.

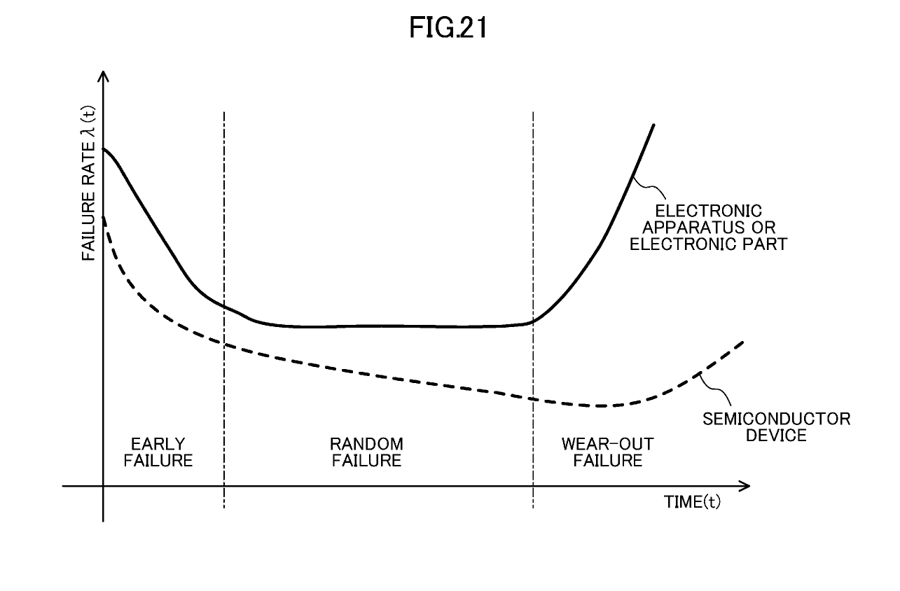

FIG. 21 shows typical failure rate curves of an electronic apparatus or electronic part and a semiconductor device. These curves are a so-called bathtub curve, in which, for example, a period of time corresponding to the life of an electronic apparatus is divided into an early failure period, a random failure period, and a wear-out failure period.

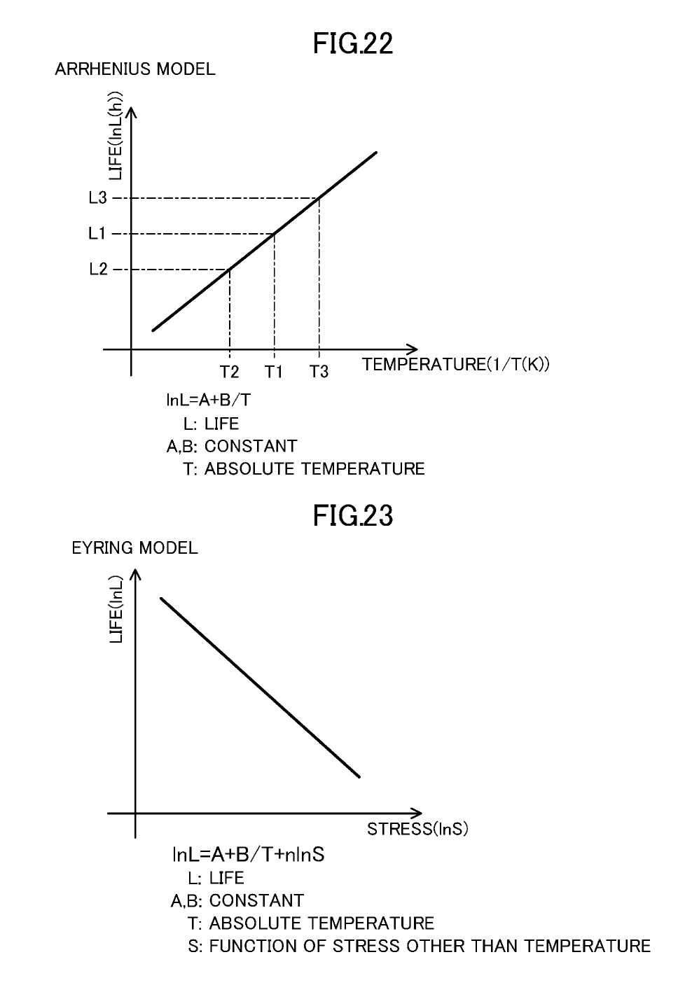

FIG. 22 is a diagram showing a graph and equation for estimating a life based on the Arrhenius model. The equation represents a temperature-life relationship and is a commonly and widely known life estimation model. As can be seen from the model, the degradation of an electronic apparatus is accelerated with an increase in temperature, and the life is inversely proportional to an absolute temperature T.

FIG. 23 is a diagram showing a graph and equation for estimating a life based on the Eyring model. This is a model in which stress, humidity, voltage, etc. are taken into account as factors which determine a life, in addition to a temperature. In general, it is known that the degradation of an electronic apparatus is accelerated with an increase in voltage, and the life is inversely proportional to the n-th power of voltage. Although the equation representing a voltage-life relationship varies significantly, depending on the configuration of the electronic apparatus, the value of the exponent n is typically n=2-4.

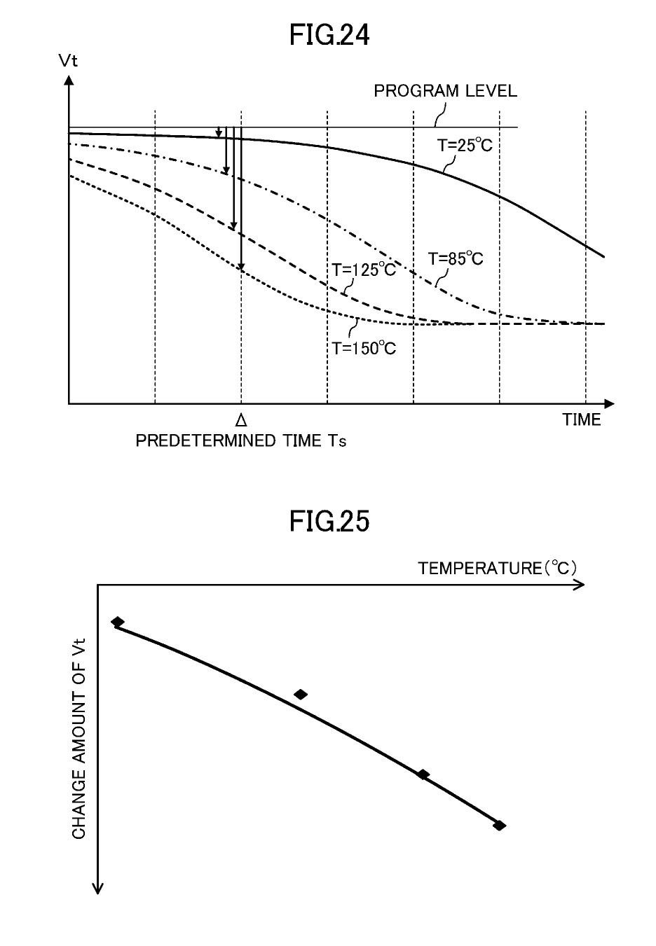

FIG. 24 is a diagram showing theoretical lines indicating the degradation over time of the memory cell Vt of a typical flash memory under different temperature conditions. The horizontal axis indicates time and the vertical axis indicates memory cell Vts. The different lines in the graph indicate changes in the memory cell Vt at different temperatures.

FIG. 25 is a diagram showing a relationship between the change amount of the memory cell Vt and a temperature in a predetermined time Ts of FIG. 24. The horizontal axis indicates temperatures and the vertical axis indicates Vt change amounts.

A flash memory can electronically change the memory cell Vt, and can hold the changed memory cell Vt even in the absence of power supply. Exactly speaking, a flash memory cell cannot hold the memory cell Vt at exactly the same level, i.e., the memory cell Vt decreases over time as shown in FIG. 24. This is a property common to various types of flash memory. The change rate is significantly affected by temperature and increases with an increase in temperature. Therefore, the memory cell Vt after a flash memory has been idle for a predetermined period of time varies depending on temperature as shown in FIG. 25, and the change in the memory cell Vt increases with an increase in temperature. A flash memory stores data 0 and 1 by utilizing a difference of the memory cell Vt. If the memory cell Vt changes significantly after the memory cell Vt is electrically set to a desired value (data write operation), the data is likely to disappear. It is more difficult to retain data as a temperature increases.

In the present disclosure, the property that the memory cell Vt is changed by heat, which makes it difficult to retain data (commonly called “retention property”) is positively utilized. The change in the memory cell Vt is a function of time and increases over time as shown in FIG. 24. On the other hand, the change in the memory cell Vt is also a function of temperature and increases with an increase in temperature as shown in FIG. 25. The change in the memory cell Vt thus determined based on a temperature and a time is determined based on the total amount of thermal stress applied to the flash memory cell. Conversely, the total amount of thermal stress can be obtained based on the change in the memory cell Vt. This is the principle based on which the flash memory cell can be used as a thermal sensor for stress. As a result, compared to sensors (e.g., a thermistor etc.) which return temperature information in real time, the present disclosure provides a sensor having excellent features, such as that thermal stress received in the time axis direction can be accumulated in the sensor element, that thermal stress occurring in the absence of power supply can also be sensed and accumulated, etc.

A flash memory cell is written/erased by applying a voltage thereto and thereby changing the memory cell Vt. A predetermined voltage or more needs to be applied in order to set the memory cell Vt to a desired level. However, even if the applied voltage is lower than or equal to a voltage which is required for write/erase operation, the memory cell Vt of the flash memory slightly changes. In an actual flash memory cell array, a plurality of memory cells share a word line or a bit line, and therefore, a voltage lower than or equal to a voltage which is required for write/erase operation is applied to a non-selected cell, whose memory cell Vt changes, which makes it difficult to retain data.

In the present disclosure, the property (commonly called “disturb”) that the memory cell Vt is changed by a low voltage, which makes it difficult to retain data, is positively utilized in addition to the change in the memory cell Vt due to heat. The change in the memory cell Vt is a function of time, similar to the change due to thermal stress, and increases over time. On the other hand, the change in the memory cell Vt is also a function of voltage, and increases with an increase in voltage. The change in the memory cell Vt thus determined based on a temperature and a time is determined based on the total amount of voltage stress applied to the flash memory cell. Conversely, the total amount of voltage stress can be obtained based on the change in the memory cell Vt. This is the principle based on which the flash memory cell can be used as a voltage sensor for stress. As a result, similar to thermal stress, stress can be accumulated in a sensor element in the time axis direction. Also, when power is not supplied, voltage stress does not exist, and therefore, sensing is not required.

As a method for predicting the life of an electronic apparatus using the total amounts of thermal stress and voltage stress accumulated in a flash memory cell, there is a method using a life model, such as the Arrhenius model of FIG. 22, the Eyring model of FIG. 23, etc. As an example, it is assumed that an electronic apparatus has the Arrhenius plot of FIG. 22. The Arrhenius plot is obtained from experiment data, such as the result of a reliability test etc. The slope is determined by activation energy which depends on the material or production method of the electronic apparatus. Therefore, the slope typically varies from electronic apparatus to electronic apparatus. Here, if it is assumed that the upper limit of the use/non-use temperature of the electronic apparatus is a temperature T1, the life is L1 when the electronic apparatus continues to be used/unused at a temperature which is the upper limit of the guaranteed temperature. The life L1 is a usable period. If the electronic apparatus is used/unused at a temperature T2 which is higher than the upper limit temperature, the degradation of the electronic apparatus proceeds more quickly. In this case, even during the usable period L1, if a life L2 determined by the temperature T2 has expired, a failure or an accident is likely to occur. If the electronic apparatus is used at a temperature which is lower than or equal to a temperature T3 lower than the upper limit temperature, even then when the usable period L1 has expired, a failure is less likely to occur. However, if a life L3 determined by the temperature T3 has expired, a failure or an accident is still likely to occur. In other words, the timing of occurrence of a failure is determined by the total amount of thermal stress which has been applied to the electronic apparatus, but not by a period of time during which the electronic apparatus has been used/unused. Therefore, the life can be predicted using a sensor cell including the flash memory cell of the present disclosure which can accumulate stress. Specifically, the amount of thermal stress which has been applied to the flash memory cell is reflected in the change in the memory cell Vt, and therefore, can be known by reading out the change in the memory cell Vt. On the other hand, the total amount of thermal stress which is likely to cause a failure is the total amount of thermal stress which has been applied at the upper limit temperature T1 during a period of time corresponding to the life L1 during which the electronic apparatus has been used/unused. Therefore, the change amount of the memory cell Vt obtained after that total amount of thermal stress has been applied is previously known. Therefore, if the change amount of the memory cell Vt which has been generated until now is subtracted from that change amount, it can be estimated how much thermal stress will have been applied from now until the occurrence of a failure. Although it has been assumed above that the life is equal to the usable period, the usable period is typically set to be shorter than the life for a safety margin.

The method for predicting the life using voltage stress is basically similar to that which uses thermal stress. The total amount of voltage stress which is likely to cause a failure may be determined based on the Eyring model of FIG. 23 etc. Note that attention should be paid to a bias voltage for causing a change in the memory cell Vt of the flash memory, and the bias voltage does not need to be equal to the power supply voltage of an electronic apparatus whose life is to be predicted. The bias voltage may be set to an optimum voltage appropriate to characteristics of the cell. Note that if a method for applying the bias voltage to the cell is selected so that the bias voltage is associated with a change in the power supply voltage of the electronic apparatus, the total amount of voltage stress can be more accurately calculated.

Next, specific operation of the sensor cells M00 and M11 will be described.

The sensor cell M00 of FIGS. 19A and 19B is one cell of the sensor cell array 2018. Here, the sensor cell M00 is assigned the function of detecting and accumulating thermal stress. The sensor cell M00 is shipped after the threshold voltage (Vt) is adjusted to a predetermined value Vt0 during a manufacturing step, such as testing etc. In this example, the initial value Vt0 is set to be high, and this state is defined as a written state, and stored data is defined as zero (“0”).

A potential of 0 V which is a ground level is applied to each node of the sensor cell M00 in the presence of applied thermal stress, via the word line WL0, the bit line BL0, or the source line SL0. This bias voltage state is the same in the presence and absence of power supply to the microcomputer 2001.

The state of the memory cell Vt is read out in a manner basically similar to that of a typical flash memory cell. The ground level 0 V is applied to the source line SL0, and the bit line BL0 is precharged, and thereafter, the potential of the word line WL0 is increased by the word line driver 2031. A potential changed due to a cell current flowing through the sensor cell M00 at that time is amplified by the sense amplifier 2017 connected to the Y decoder 2020. This is different from typical read operation in that read operation is repeatedly performed while changing the potential of the word line WL0, and the memory cell Vt is obtained from the potential of the word line WL0 when data determined by the sense amplifier 2017 is reversed. Instead of changing the potential of the word line WL0, the reference potential/current for determination by the sense amplifier 2017 may be changed. However, it is preferable that the reference potential/current should not be changed, for the purpose of stable operation of the sense amplifier 2017.

By comparing a difference between the obtained memory cell Vt and the predetermined initial value Vt0 with the change amount of the memory cell Vt which is obtained when thermal stress has been applied so that the end of the life is reached, the remainder of the usable period can be estimated. Note that the memory cell Vt is typically converted into a register value which is used to control the power supply circuit 2021 which supplies a word line potential.

It takes an extra time and power to repeatedly perform read operation while changing the potential of the word line WL0. Therefore, it is more efficient to previously determine the memory cell Vt which causes an event and return only the result of reading of the word line potential corresponding to the memory cell Vt than to calculate the memory cell Vt itself. This is possible because the initial value Vt0 of the sensor cell M00 and the change amount of the memory cell Vt which causes an event are previously determined.

The sensor cell M11 of FIGS. 20A and 20B is one cell of the sensor cell array 2018. Here, the sensor cell M11 is assigned the function of detecting and accumulating voltage stress. The sensor cell M11 is shipped after the threshold voltage (Vt) is adjusted to a predetermined value Vt1 during a manufacturing step, such as testing etc. In this example, the initial value Vt1 is set to be low, and this state is defined as an erased state, and stored data is defined as one (“1”). Here, the reason why the initial memory cell Vt is different from that of the sensor cell M00 for detecting thermal stress is that the influence of thermal stress is minimized. In general, the change amount of the memory cell Vt due to thermal stress increases with an increase in the absolute value. If the memory cell Vt of a cell for detecting voltage stress is changed due to thermal stress, the accuracy of detection of voltage stress decreases. To avoid this, the above setting is provided.

A potential of 0 V which is a ground level is applied to the drain or source of the sensor cell M11 in the presence of applied voltage stress, via the bit line BL1 or the source line SL0. A disturb voltage Vg is applied to the gate via the word line WL1. The application of the positive voltage to the gate causes a voltage between the floating gate and source or drain of the sensor cell M11. A tunnel current caused by the voltage causes injection of electrons into the floating gate, resulting in an increase in the memory cell Vt. Note that it is necessary to prevent the rate of the increase from reaching the saturation level even if the bias voltage is applied for a period of time corresponding to the life of the electronic apparatus. To do so, the disturb voltage Vg is adjusted. Note that the disturb voltage Vg is more preferably changed in association with the power supply voltage of the electronic apparatus whose life is to be estimated. If the above conditions related to the saturation level are satisfied, the power supply voltage of the electronic apparatus may be optionally applied directly to the word line WL1 without being passed through a level shifter etc. The disturb voltage Vg is not applied to the sensor cell MOO for detecting thermal stress, because the word line is different.

This bias voltage state occurs only in the presence of power supply to the microcomputer 2001. It may be selected or determined whether or not the disturb voltage Vg is invariably applied in the presence of power supply, depending on the electronic apparatus whose life is to be predicted. For example, in FIG. 16, when the life of the power supply block 2006 is to be predicted, the disturb voltage Vg is invariably applied during the power supply, and when the life of the motor 2003 is to be predicted, the disturb voltage Vg is applied only during rotation of the motor 2003. Moreover, when both the lives of the power supply block 2006 and the motor 2003 are to be predicted, another flash memory cell having a different word line may be added.

Note that the method for reading out the state of the memory cell Vt is the same as that of the sensor cell M00 for detecting thermal stress and will not be described.

Next, a flow of steps of predicting the remainder of the life of an electronic apparatus based on the total amount of stress and controlling operation of the electronic apparatus will be described with reference to mainly FIG. 17. Read operation is repeatedly performed while changing a word line voltage of the sensor cell array 2018 by changing a power supply voltage from the power supply circuit 2021. The resulting information about the change amount of the memory cell Vt is typically transferred to the control circuit 2022 as a register value for controlling a voltage regulator for the power supply circuit 2021. In the control circuit 2022, the remainder of the life is calculated by referencing a table indicating a relationship between the change amount of the memory cell Vt and the total amount of stress, and the information is transferred to the CPU 2011.

To further simplify the operation, read operation may be performed using a word line voltage corresponding to a predetermined memory cell Vt, and only the determination result may be transferred to the CPU 2011. Examples of the predetermined memory cell Vt include that at the time when the end of the life is reached, that less than one year before the end of the life in ordinary use, that less than two years before the end of the life in ordinary use, etc. In this method, the result of read operation may be transferred as the result of determination directly to the CPU 2011, i.e., a complicated process (referencing the table, etc.) may not be required, whereby the control circuit 2022 can be simplified.

Alternatively, the word line voltage corresponding to the predetermined memory cell Vt may be held in the control circuit 2022 as the register value for controlling the regulator for the power supply circuit 2021. Alternatively, the word line voltage corresponding to the predetermined memory cell Vt may be stored in the memory cell array 2014, and transferred by the control circuit 2022 to a register which controls the regulator.

The control circuit 2022 is used basically until the life is calculated. The CPU 2011 is preferably assigned the function of controlling blocks/units of the electronic apparatus using that information. This is because the CPU 2011 is inherently prepared for controlling the blocks/units. If the control circuit 2022 of the life prediction system of the present disclosure is assigned the control function, the design of the control circuit 2022 needs to be modified, depending on each block/unit of the electronic apparatus, leading to less efficiency. Note that if the control circuit 2022 is provided in an electronic apparatus which does not include a controller, such as the CPU 2011, the control circuit 2022 may have the control function.

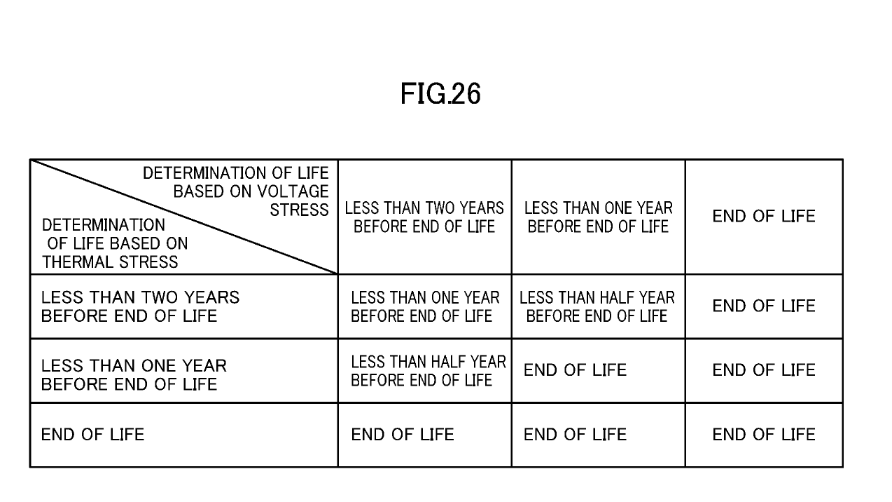

FIG. 26 is diagram showing a life determination table in which thermal stress and voltage stress are combined. If there are a plurality of information items related to the total amount of stress, the life determination is complicated. For example, in FIG. 18, if information about thermal stress is obtained from the sensor cell M00 and information about voltage stress is obtained from the sensor cell M11, it is necessary to predict the life which is determined based on a combination of factors, i.e., heat and voltage. If either the total amount of thermal stress or the total amount of voltage stress has exceeded a level corresponding to the life, it can be determined that the life of the electronic apparatus has expired. If both the total amount of thermal stress and the total amount of voltage stress have reached respective levels corresponding to less than one year before the life, in some cases it should be determined that the life of the electronic apparatus has expired due to the combined effect. Specifically, the determination table of FIG. 26 may be produced based on the actual strength etc. of the electronic apparatus, and a combined life prediction determination may be performed. The determination table may be stored in the control circuit 2022, or alternatively, may be stored in the memory cell array 2014 and read out by the control circuit 2022.

The CPU 2011 takes a predetermined measure based on the remainder-of-life information received from the control circuit 2022. For example, when receiving from the control circuit 2022 the determination result that the remainder of the life is less than one year in ordinary use, the CPU 2011 controls the I/O circuit 2012 so that the lamp 2005 of FIG. 16 is flickered, thereby notifying the user that the life will expire in the near future. When the determination result that the life has expired is transferred to the CPU 2011, the CPU 2011 also controls the I/O circuit 2012 so that the lamp 2005 of FIG. 16 is flickered, thereby notifying the user that the life has expired, and causes the method of controlling the motor 2003 to be invariably off, thereby disabling the electric fan, for example.

The information about the total amount of stress may be read from the sensor cell array 2018 and the information about the remainder of the life may be transferred to the CPU 2011 at a timing, such as when the electronic apparatus is turned on, etc. This is insufficient. If the electronic apparatus is assumed to operate all the time, the reading and transferring of the information needs to be performed every predetermined period of time during which power is supplied and the electronic apparatus is operating. To achieve this function, the control circuit 2022 may have a function of calculating the remainder of the life in response to a request from the CPU 2011 and returning the information to the CPU 2011. It is easy to generate an event at predetermined intervals by using the CPU 2011 and a functional block provided in an ordinary microcomputer. Alternatively, a measure may be taken based on the life information when any event occurs, but not at predetermined intervals.

Note that codes which are to be executed by the CPU 2011 may be stored in the memory cell array 2014, and therefore, the timing of obtaining the life information and the details of a measure based on the information may be determined by the manufacturer of the electronic apparatus. The manufacturer of the electronic apparatus has a better knowledge or skill to take the measure than that of the manufacturer of the microcomputer 2001. This is important in order to put the life prediction system into widespread use.

In the above example, a measure is taken when it is determined that the life has expired. Alternatively, if a measure should be taken for safety before the life has expired, the measure can be taken before the life has expired, without any problem.

The life information determined by the control circuit 2022 may be transferred to a control device external to the microcomputer 2001 as well as to the CPU 2011 inside the microcomputer 2001, and a measure may be taken by the external control device.

The life of the microcomputer 2001 itself including the life estimation system may be determined instead of the life of the entire electronic apparatus, and a measure may be taken.

The life estimation system may be separately implemented as an LSI to estimate the life of the electronic apparatus.

In addition to the flash memory cell, the device for detecting and accumulating stress may be a non-volatile memory, such as a ferroelectric random access memory (FeRAM), a magneto-resistive random access memory (MRAM), a phase change random access memory (PRAM), etc., which have characteristics changing depending on stress.

If the memory cell Vt of the sensor cell M00 is changed due to thermal stress which occurs during a manufacturing step in the manufacturer of the electronic apparatus, such as reflow soldering which is performed when the microcomputer 2001 is mounted on a substrate, etc., an error may occur in life estimation due to the change. To reduce or prevent the error, the threshold voltage (Vt) may be reset during the manufacturing process in the manufacturer. A method for resetting the threshold voltage is easily carried out similar to a typical flash memory write method and will not be described.

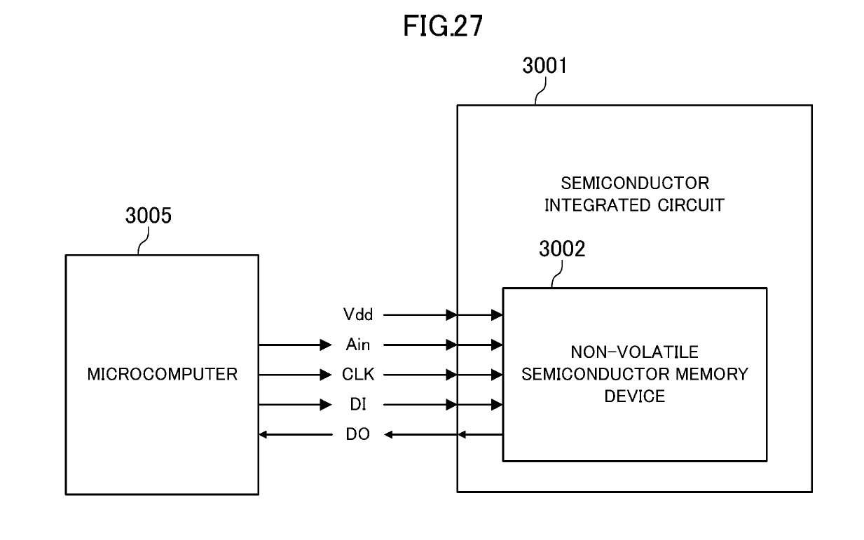

FIG. 27 shows an example semiconductor system including the non-volatile semiconductor memory device of the present disclosure, where the semiconductor system includes a plurality of chips. The semiconductor system includes a semiconductor integrated circuit 3001 including a non-volatile semiconductor memory device 3002 of the present disclosure, and a microcomputer 3005 externally connected to the semiconductor integrated circuit 3001. The non-volatile semiconductor memory device 3002 and the microcomputer 3005 are connected to each other via the semiconductor integrated circuit 3001 using input signal lines Ain, CLK, and DI and the output signal line DO. The non-volatile semiconductor memory device 3002 is operated by a signal output from the microcomputer 3005 being input from the input signal lines Ain, CLK, and DI to the non-volatile semiconductor memory device 3002. When a signal for detecting the life is input from circuitry external to the non-volatile semiconductor memory device 3002, an output signal from the output signal line DO is output to circuitry external to the semiconductor integrated circuit 3001.

Operation in the flow of FIG. 9 will be described with reference to FIG. 27. When an external request signal is input as shown in FIG. 9, a signal is input from the microcomputer 3005 of FIG. 27 to the non-volatile semiconductor memory device 3002. Based on the input signal, operation (the read operation in step 302 of FIG. 9) is performed in the non-volatile semiconductor memory device 3002. The result of the read operation in the non-volatile semiconductor memory device 3002 is output from the output signal line DO of the semiconductor integrated circuit 3001 (detection signal output in step 306 of FIG. 9).

For example, when the set life has not expired, a low-level signal is output as a detection signal to circuitry external to the non-volatile semiconductor memory device 3002, and when the set life has expired, a high-level signal is output as a detection signal to circuitry external to the non-volatile semiconductor memory device 3002, whereby the life can be determined. Although, in this example, the detection signal transitions from the low level to the high level, the output conditions (the low level and the high level) may be switched.

If the present disclosure is included in every electronic apparatus, the detection of the degree of a degradation over time of an electronic apparatus can be put into widespread use, and accidents due to use of an electronic apparatus having excessive stress can be reduced or prevented, whereby the safety of the user can be ensured. For manufacturers, the present disclosure will be an important technique for doing their responsibility to the safety of their products.

For example, if the present disclosure is applied to an electronic apparatus which is used within a wide temperature range, such as an in-car device, a mobile device, etc., it is possible to prevent unexpected runaway of a product which may lead to the death of a human. In addition to such a serious accident that may lead to the death of a human, disadvantages such as loss of important data, missing of opportunities, etc. can be reduced or prevented by predicting a failure of an electronic apparatus and thereby taking a pre-emptive measure, whereby the usability of the electronic apparatus can be improved.

Thus, according to the present disclosure, the safety and reliability of many electronic apparatuses used in society are improved, contributing to the construction of safer society.

Ambient temperature can also be detected by detecting the degree of the degradation over time. Therefore, the present disclosure is applicable to techniques of reducing power, such as frequency control etc., at various temperatures.

The present disclosure also has the function of storing the history of applied heat. Therefore, the present disclosure may be applicable to, for example, a system including heat history management tags for fresh foods, pharmaceutical products, etc. and a mechanism for determining the tags.

A tag employing the present disclosure may be attached to, for example, a fresh food or pharmaceutical product which is not allowed to be stored at a predetermined temperature or more or frozen fish which is not allowed to be temporarily thawed. When the state of the product needs to be checked, the determination mechanism (reader) may be used to check the state of the tag, whereby it can be determined whether or not there has been no power supply during preservation and the product has been left in an inappropriate temperature environment, for example.

In a semiconductor memory device having an error checking and correction (ECC) function, 8-bit data for error correction is provided for each 64-bit data in a memory, and if a 1-bit error occurs in 64 bits, the error is detected and corrected. When the error correction data is 8 bits, then if an error occurs in two or more bits in the memory, the error cannot be corrected. On the other hand, if a semiconductor memory device has been used for a long time, an error is more likely to occur in data due to thermal stress or a turn-on period. Therefore, the present disclosure may be applied to the semiconductor memory device with the ECC function to detect thermal stress or a turn-on period which has affected the semiconductor memory device. When the set life has expired, the number of bits of data for error correction for the semiconductor memory device with the ECC function is increased from the original 8 bits, whereby an error of 2 bits or more can be detected and corrected. In addition, an excessive number of bits do not need to be prepared for the data for error correction.

What is claimed is:

1. A non-volatile semiconductor memory device for detecting a degree of a degradation over time due to an operating temperature and an operating time, comprising:
a memory cell array including a plurality of non-volatile memory cells;
a plurality of word lines connected to gates of the plurality of non-volatile memory cells;
a plurality of bit lines connected to drains or sources of the plurality of non-volatile memory cells;
a word line select circuit configured to select one of the plurality of word lines and apply a voltage to the selected word line;
a bit line select circuit configured to select one of the plurality of bit lines and apply a voltage to the selected bit line;
a sense amplifier circuit configured to detect a state of a non-volatile memory cell selected by the word line select circuit and the bit line select circuit; and
a control circuit configured to control the non-volatile semiconductor memory device,
wherein
the memory cell array is divided into a first block including a non-volatile memory cell for accumulating the degradation over time and a second block including a non-volatile memory cell for storing data, and
the word line select circuit and the bit line select circuit select a first word line and a first bit line connected to the second block to access the non-volatile memory cell for storing data of the second block, and selects a second word line or a second bit line connected to the first block to apply a stress voltage to the non-volatile memory cell for accumulating the degradation over time of the first block.

2. The non-volatile semiconductor memory device of claim 1, wherein
based on an externally input request signal, the sense amplifier circuit detects the state of the non-volatile memory cell for storing the degradation over time of the first block, and when the sense amplifier circuit detects that the state of the non-volatile memory cell for storing the degradation over time of the first block is a predetermined state, the control circuit outputs a detection signal indicating that the degradation over time has proceeded.

3. The non-volatile semiconductor memory device of claim 1, wherein
the non-volatile semiconductor memory device itself uses the sense amplifier circuit to regularly detect the state of the non-volatile memory cell for accumulating the degradation over time of the first block, and when the sense amplifier circuit detects that the state of the non-volatile memory cell for storing the degradation over time of the first block is a predetermined state, the control circuit outputs a detection signal indicating that the degradation over time has proceeded.

4. The non-volatile semiconductor memory device of claim 1, wherein
the non-volatile memory cell includes a memory cell which changes a threshold voltage value by storing electrons in a floating gate or an oxynitride film, and
based on an externally input request signal, the sense amplifier circuit detects the threshold voltage value of the non-volatile memory cell for storing the degradation over time of the first block, and when the sense amplifier circuit detects that the threshold voltage value of the non-volatile memory cell for storing the degradation over time of the first block has reached a predetermined threshold voltage value, the control circuit outputs a detection signal indicating that the degradation over time has proceeded.

5. The non-volatile semiconductor memory device of claim 1, wherein
the non-volatile memory cell includes a memory cell which changes a threshold voltage value by storing electrons in a floating gate or an oxynitride film, and
the non-volatile semiconductor memory device itself uses the sense amplifier circuit to regularly detect the threshold voltage value of the non-volatile memory cell for accumulating the degradation over time of the first block, and when the sense amplifier circuit detects that the threshold voltage value of the non-volatile memory cell for storing the degradation over time of the first block has reached a predetermined threshold voltage value, the control circuit outputs a detection signal indicating that the degradation over time has proceeded.

6. The non-volatile semiconductor memory device of claim 1, wherein,
a sensor block having the memory cell array, and a control and determination block for controlling and determining the sensor block, each include a separate semiconductor chip.

7. A semiconductor integrated circuit including the non-volatile semiconductor memory device of claim 1, wherein
the semiconductor integrated circuit has a function of outputting the detection signal indicating that the degradation over time has proceeded, to circuitry external to the chip, in response to a request signal for checking whether or not the degradation over time has proceeded, the request signal being input from the circuitry external to the chip.

8. A non-volatile semiconductor memory device for detecting a degree of a degradation over time due to an operating temperature and an operating time, comprising:
a memory cell array including a plurality of non-volatile memory cells;
a plurality of word lines connected to gates of the plurality of non-volatile memory cells;
a plurality of bit lines connected to drains or sources of the plurality of non-volatile memory cells;
a word line select circuit configured to select one of the plurality of word lines and apply a voltage to the selected word line;
a bit line select circuit configured to select one of the plurality of bit lines and apply a voltage to the selected bit line;
a sense amplifier circuit configured to detect a state of a non-volatile memory cell selected by the word line select circuit and the bit line select circuit; and
a control circuit configured to control the non-volatile semiconductor memory device,
wherein
the memory cell array is divided into a first block including a non-volatile memory cell for accumulating the degradation over time and a second block including a non-volatile memory cell for storing data, and
the word line select circuit and the bit line select circuit select a word line or a bit line connected to the first block to apply a stress voltage to the non-volatile memory cell for accumulating the degradation over time of the first block during a period of time that a power supply voltage is being applied to the non-volatile semiconductor memory device.

9. The non-volatile semiconductor memory device of claim 8, wherein,
based on an externally input request signal, the sense amplifier circuit detects the state of the non-volatile memory cell for storing the degradation over time of the first block, and when the sense amplifier circuit detects that the state of the non-volatile memory cell for storing the degradation over time of the first block is a predetermined state, the control circuit outputs a detection signal indicating that the degradation over time has proceeded.

10. The non-volatile semiconductor memory device of claim 8, wherein,
the non-volatile semiconductor memory device itself uses the sense amplifier circuit to regularly detect the state of the non-volatile memory cell for accumulating the degradation over time of the first block, and when the sense amplifier circuit detects that the state of the non-volatile memory cell for storing the degradation over time of the first block is a predetermined state, the control circuit outputs a detection signal indicating that the degradation over time has proceeded.

11. The non-volatile semiconductor memory device of claim 8, wherein,
the non-volatile memory cell includes a memory cell which changes a threshold voltage value by storing electrons in a floating gate or an oxynitride film, and
based on an externally input request signal, the sense amplifier circuit detects the threshold voltage value of the non-volatile memory cell for storing the degradation over time of the first block, and when the sense amplifier circuit detects that the threshold voltage value of the non-volatile memory cell for storing the degradation over time of the first block has reached a predetermined threshold voltage value, the control circuit outputs a detection signal indicating that the degradation over time has proceeded.

12. The non-volatile semiconductor memory device of claim 8, wherein,
the non-volatile memory cell includes a memory cell which changes a threshold voltage value by storing electrons in a floating gate or an oxynitride film, and
the non-volatile semiconductor memory device itself uses the sense amplifier circuit to regularly detect the threshold voltage value of the non-volatile memory cell for accumulating the degradation over time of the first block, and when the sense amplifier circuit detects that the threshold voltage value of the non-volatile memory cell for storing the degradation over time of the first block has reached a predetermined threshold voltage value, the control circuit outputs a detection signal indicating that the degradation over time has proceeded.

13. The non-volatile semiconductor memory device of claim 8, wherein,
a sensor block having the memory cell array, and a control and determination block for controlling and determining the sensor block, each include a separate semiconductor chip.

14. A semiconductor integrated circuit including the non-volatile semiconductor memory device of claim 8, wherein
the semiconductor integrated circuit has a function of outputting the detection signal indicating that the degradation over time has proceeded, to circuitry external to the chip, in response to a request signal for checking whether or not the degradation over time has proceeded, the request signal being input from the circuitry external to the chip.

15. A non-volatile semiconductor memory device for detecting a degree of a degradation over time due to an operating temperature and an operating time, comprising:
a memory cell array including a plurality of non-volatile memory cells;
a plurality of word lines connected to gates of the plurality of non-volatile memory cells;
a plurality of bit lines connected to drains or sources of the plurality of non-volatile memory cells;
a word line select circuit configured to select one of the plurality of word lines and apply a voltage to the selected word line;
a bit line select circuit configured to select one of the plurality of bit lines and apply a voltage to the selected bit line;
a sense amplifier circuit configured to detect a state of a non-volatile memory cell selected by the word line select circuit and the bit line select circuit; and
a control circuit configured to control the non-volatile semiconductor memory device,
wherein
the memory cell array is divided into a first block including a non-volatile memory cell for accumulating a degradation over time and a second block including a non-volatile memory cell for storing data, and
the word line select circuit and the bit line select circuit select a first word line and a first bit line connected to the second block to access the non-volatile memory cell for storing data of the second block, and selects a second word line or a second bit line, of the plurality of word lines and the plurality of bit lines connected to the first block, to apply a stress voltage to a non-volatile memory cell for accumulating a first degradation over time of the first block, and do not select a third word line or a third bit line, of the plurality of word lines and the plurality of bit lines connected to the first block, and therefore do not apply a stress voltage to a non-volatile memory cell for accumulating a second degradation over time of the first block.

16. The non-volatile semiconductor memory device of claim 15, wherein, based on an externally input request signal, the sense amplifier circuit detects the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

17. The non-volatile semiconductor memory device of claim 15, wherein,
the non-volatile semiconductor memory device itself uses the sense amplifier circuit to regularly detect the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

18. The non-volatile semiconductor memory device of claim 15, wherein,
the non-volatile memory cell includes a memory cell which changes a threshold voltage value by storing electrons in a floating gate or an oxynitride film, and
based on an externally input request signal, the sense amplifier circuit detects the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

19. The non-volatile semiconductor memory device of claim 15, wherein,
the non-volatile memory cell includes a memory cell which changes a threshold voltage value by storing electrons in a floating gate or an oxynitride film, and
the non-volatile semiconductor memory device itself uses the sense amplifier circuit to regularly detect the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

20. A non-volatile semiconductor memory device for detecting a degree of a degradation over time due to an operating temperature and an operating time, comprising:
a memory cell array including a plurality of non-volatile memory cells;
a plurality of word lines connected to gates of the plurality of non-volatile memory cells;
a plurality of bit lines connected to drains or sources of the plurality of non-volatile memory cells;
a word line select circuit configured to select one of the plurality of word lines and apply a voltage to the selected word line;
a bit line select circuit configured to select one of the plurality of bit lines and apply a voltage to the selected bit line;
a sense amplifier circuit configured to detect a state of a non-volatile memory cell selected by the word line select circuit and the bit line select circuit; and
a control circuit configured to control the non-volatile semiconductor memory device,
wherein
the memory cell array is divided into a first block including a non-volatile memory cell for accumulating a degradation over time and a second block including a non-volatile memory cell for storing data, and
the word line select circuit and the bit line select circuit select a first word line or a first bit line, of the plurality of word lines and the plurality of bit lines connected to the first block, to apply a stress voltage to a non-volatile memory cell for accumulating a first degradation over time of the first block, and do not select a second word line or a second bit line, of the plurality of word lines and the plurality of bit lines connected to the first block, and therefore do not apply a stress voltage to a non-volatile memory cell for accumulating a second degradation over time of the first block, during a period of time that a power supply voltage is being applied to the non-volatile semiconductor memory device.

21. The non-volatile semiconductor memory device of claim 20, wherein,
based on an externally input request signal, the sense amplifier circuit detects the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

22. The non-volatile semiconductor memory device of claim 20, wherein,
the non-volatile semiconductor memory device itself uses the sense amplifier circuit to regularly detect the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

23. The non-volatile semiconductor memory device of claim 20, wherein,
the non-volatile memory cell includes a memory cell which changes a threshold voltage value by storing electrons in a floating gate or an oxynitride film, and
based on an externally input request signal, the sense amplifier circuit detects the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

24. The non-volatile semiconductor memory device of claim 20, wherein,
the non-volatile memory cell includes a memory cell which changes a threshold voltage value by storing electrons in a floating gate or an oxynitride film, and
the non-volatile semiconductor memory device itself uses the sense amplifier circuit to regularly detect the states of the non-volatile memory cell for storing the first degradation over time and the non-volatile memory cell for storing the second degradation over time, of the first block, and when the sense amplifier circuit detects that a difference between the states of the non-volatile memory cell for storing the first degradation over time and the non-volatile memory cell for storing the second degradation over time has a predetermined value, the control circuit outputs a detection signal indicating that the degradation over time has proceeded.

25. A semiconductor integrated circuit comprising:
a non-volatile semiconductor memory device configured to detect a degree of a degradation over time due to an operating temperature and an operating time; and
a central processing device configured to control an apparatus,
wherein
the non-volatile semiconductor memory device and the central processing device are provided on a same semiconductor substrate, and
the non-volatile semiconductor memory device outputs to the central processing device a detection signal indicating that the degradation over time has proceeded.

26. The semiconductor integrated circuit of claim 25, wherein
the central processing device outputs to the non-volatile semiconductor memory device a request signal for checking how much the degradation over time has proceeded.

27. A semiconductor integrated circuit comprising:
a non-volatile semiconductor memory device configured to detect a degree of a degradation over time due to an operating temperature and an operating time; and
a central processing device configured to control an apparatus,
wherein
the non-volatile semiconductor memory device outputs to the central processing device a detection signal indicating that the degradation over time has proceeded.

28. The semiconductor integrated circuit of claim 27, wherein
the central processing device outputs to the non-volatile semiconductor memory device a request signal for checking how much the degradation over time has proceeded.
